(19) United States
(12) Patent Application Publication
(10) Pub. No.: US 2025/0185223 A1
(43) Pub. Date: Jun. 5, 2025

(54) SYSTEM FOR COOLING IN A HEADSET DISPLAY

(71) Applicant: Meta Platforms Technologies, LLC, Menlo Park, CA (US)

(72) Inventors: Giti Karimi Moghaddam, Saratoga, CA (US); Leonardo Aldana, Tracy, CA (US); Ryan Fleming, Oakland, CA (US); Sarah Graber, Seattle, WA (US); Christina Yee, Redmond, WA (US); Shannon X Yang, Newcastle, WA (US); Ian Campbell, Seattle, WA (US)

(21) Appl. No.: 18/955,360

(22) Filed: Nov. 21, 2024

Related U.S. Application Data
(60) Provisional application No. 63/604,276, filed on Nov. 30, 2023.

(51) Int. Cl. H05K 7/20; H05K 5/02

(52) U.S. Cl. CPC H05K 7/20963; H05K 5/0213; H05K 7/20154; H05K 7/20336; H05K 7/2039; H05K 7/20972; H05K 7/2099

(57) ABSTRACT

An electronic system is described that includes a headset device and associated cooling system. The headset device may be configured to physically separate high temperature components from other components of the headset device into multiple cavities. In some cases, the headset device may be divided into a display cavity and an electronics cavity to separate the display components from other components of the headset device.

### CROSS-REFERENCE TO RELATED APPLICATIONS

This application claims priority to U.S. Provisional Patent Application No. 63/604,276, filed 30 Nov. 2023, the disclosure of which is incorporated, in its entirety, by this reference.

### BACKGROUND

Today, wearable electronic devices that provide virtual or mixed reality experiences are becoming more and more commonplace. Many of these wearable electronic devices are equipped with displays that are worn over the eyes and in contact with a face of the user to stream image data including the virtual or mixed reality objects as well as, in some cases, image data of the surrounding physical environment. In some cases, the integration of particular display technologies and/or processing technologies may not be adequately cooled using existing thermal management architectures.

### SUMMARY

This disclosure includes techniques and implementations of an electronic system including a head-mounted display system (e.g., a headset, such as a virtual-reality headset, an augmented-reality headset, or augmented-reality glasses, etc.) and associated cooling system. The headset system may be equipped with one or more displays and/or optical modules to display visual content. In some cases, the headset system may include displays or optical modules. The first display and/or optical module may be positioned to be over a right eye of a user and the second display and/or optical module may be positioned to be over a left eye of the user to provide a three-dimensional immersive viewing experience when the headset is worn by the user. In some implementations, the displays may be OLEDS or micro OLEDs (uOLEDs).

In some examples, in order to maintain the operating temperature below the desired temperature threshold, the headset device may be configured to physically separate high temperature components, such as the computing components (e.g., data processors, graphics processors, memory or storage components, and the like), from other components (e.g., the display components, image devices, projectors, and the like) of the headset device. In some cases, the computing components may be separated from the display components by implementation of a back of the head system (e.g., a rear system) and a front of the head system (e.g., a front system). In these examples, some or all of the computing components may be configured in the rear system that is positioned, during use, behind the head of the user and some or all of the display components may be configured in a front system that is positioned, during use, over the eyes of the user. The front system may be coupled to the rear system via one or more straps or other adjustable components to allow the user to configure a size and position of the headset device with respect to their head.

In some cases, the front system may be further physically divided via a separator wall into a front cavity and a rear cavity. The separator wall may include a thermal barrier and/or be formed of a material selected with desired thermal properties. For example, the separator wall may be formed from materials including a hard or soft plastic or rubber. In some cases, the separator wall may be at least partially formed from aluminum and/or magnesium. For instance, the separator wall may have a metallic structure that includes plastic film windows to reduce overall weight of the separator and, thereby, the front system of the headset device.

The front cavity of the front system may include the various electronic components of the front system, such as the image devices (cameras, red-green-blue image devices, depth sensors, infrared sensors, video devices, and the like), projectors, measurement units (such as vibration sensors, acceleration sensors, gravity sensors, gyroscopes, magnetometers, interrail measurement units, and the like) and the rear cavity of the front system may include the display components (e.g., the uOLED panels), the display drivers, and/or the optical modules (e.g., the right and left optical modules including lenses, gratings, and the like). In this manner, the front system may include an electronics cavity and a display cavity physically divided by the separator wall. In operation, it should be understood that the temperature of the display cavity may be maintained at or below a first desired temperature threshold, while in some cases, the temperature of the electronic cavity may exceed the desired temperature threshold or may have a second, different temperature threshold.

In some implementations, the front system may include a thermal cooling system to assist in maintaining the displays at or below the desired temperature threshold. For example, the first temperature threshold of the display cavity may be at or below 40 degrees Celsius and the second temperature threshold of the electronics cavity may be at or below 70 degrees Celsius. In some cases, the front system may include air inlets along or proximate the bottom and/or side surfaces of the front system and air outlets or exits along or proximate the top surface of the headset device. The air inlets may define an opening between an exterior of the front system (e.g., open to the surrounding physical environment) and an interior of the display cavity and the outlets may define an opening between the exterior of the front system and the interior of the electronics cavity, as discussed herein.

In some implementations, the separator wall may include one or more blowers (e.g., integrated in and/or coupled to the separator wall) that extend into the electronics cavity but are configured to pull air from the display cavity into the electronics cavity. In one specific example, the front system may include ionic fans. For instance, conventional fans may be loud or otherwise distracting to a user when placed in close proximity to the face and ears of the user. This can be a particular problem in wearable headset devices, such that the fan noise and/or humming may cause the user to increase a volume of the audio output by the headset device to a level that may damage or otherwise harm the ears of the user, such as during extended use. The one or more blowers may be coupled within the electronics cavity to pull air directly into the display cavity (e.g., pull outside air into the display cavity). Each of the blowers may further be configured and positioned to exhaust air from the display cavity into the electronics cavity to cool the components of the electronics cavity. In some cases, other than the blowers, the electronics cavity and the display cavity may be sealed with respect to each other, e.g., such that substantially no air passes between the two cavities other than as exhaust air from the blowers.

Accordingly, each of the one or more blowers (e.g., ionic fans) may be positioned such that outside air is pulled through the inlets along the side/bottom surfaces of the front system into the display cavity and the outside air may first cool the display components. Next, the air is exhausted from the display cavity into the electronics cavity to cool the other electronic components of the front system and finally the air is output from the front system via the outlets along the top surface of the headset. In this manner, cooler air is used to cool the display components prior to cooling other components of the front system and the airflow is maintained over the components of both the electronics cavity and the display cavity in a generally upward direction through the front system.

In some examples, the display drivers, such as a digital display indicator control (DDIC), may be positioned within the display cavity with the other display components, such as the display panel and/or optical modules, or the DDIC may be positioned in a separate cavity (e.g., a DDIC cavity) within the display cavity. In an example in which a separate DDIC cavity is used, a thermal strap may be applied between the display cavity and the DDIC cavity to provide cooling to the DDIC. In some examples, the thermal strap may be positioned through or along the separator wall to draw the heat from the DDIC cavity into the electronic cavity. As various examples, the DDIC cavity may be sealed from the display cavity but fluidly coupled to the electronics cavity via one or more slots in the separator wall to allow the DDIC to be cooled with the air exhausted from the one or more blowers. In some examples, the DDIC cavity may be formed from a portion of the separator wall or an additional wall.

In some cases, as the air is forced through the blowers into the front cavity, the air may become pressurized to cause the air to flow upward and out via the vent at the top surface of the headset device. By pressurizing the air, the air flow may be increased and/or cause more efficient circulation within the front cavity thereby providing improved cooling for the components of the front cavity.

In some examples, camera modules or components may be positioned within the front cavity. The camera modules may be coupled to one or more heat sinks or heat spreaders (e.g., a vapor chamber, a heat pipe, an ionic fan, etc.) that may cause heat to transfer from the camera modules to the front cover or chassis of the headset display to thereby spread the heat generated by the one or more camera modules through the front surface of the headset device. For example, at least a portion of the front cover may be formed of aluminum or other heat spreading/heat sinking material to spread the heat generated by the camera modules through the chassis and at locations away from the face of the user (e.g., such that the heat distribution portions of the chassis or front cover are not in contact with the face of the user when worn). In some examples, other heat spreading structures (e.g., vapor chambers, graphite sheets, etc.) may be used to spread the heat uniformly throughout all or a portion of the chassis (e.g., throughout the front cavity).

In some examples, the display panel and/or components may also be equipped with one or more heat transfer surfaces. The heat transfer surfaces allow the transfer of heat between the outside air and the display panel to be increased, thereby assisting the display panel and/or the display cavity maintaining a temperature at or below the display cavity temperature threshold (e.g., 40 degrees Celsius).

### BRIEF DESCRIPTION OF THE DRAWINGS

FIG. 1 is an example perspective view of an example electronic display system comprising a front system and a rear system, in accordance with one or more examples.

FIG. 2 is an example side and front view of an example front system of an electronic display system having inlets and outlets, in accordance with one or more examples.

FIG. 3 is an example cross-sectional side view of an example front system of an electronic display system utilizing multiple blowers, in accordance with one or more examples.

FIG. 4 is an example view of the example portion of the front system of FIG. 1, in accordance with one or more examples.

FIG. 5 is an example cross-sectional side view of an example front system of an electronic display system of FIG. 1, in accordance with one or more examples.

FIG. 6 is an example cross-sectional top view of an example front system of an electronic display system of FIG. 1, in accordance with one or more examples.

FIG. 7 is an example cross-sectional side view of an example front system of an electronic display system of FIG. 1, in accordance with one or more examples.

FIG. 8 is another example cross-sectional side view of an example front system of an electronic display system of FIG. 1, in accordance with one or more examples.

FIG. 9 is an example perspective view of an example heat pipe, in accordance with one or more examples.

FIG. 10 is an example perspective view of an example heat pipe with an alternative configuration, in accordance with one or more examples.

FIG. 11 is an example perspective view of an example separator wall positioned in the electronics display system, in accordance with one or more examples.

FIG. 12 is an illustration of an example artificial-reality system according to some embodiments of this disclosure.

FIG. 13 is an illustration of an example artificial-reality system with a handheld device according to some embodiments of this disclosure.

FIG. 14A is an illustration of example user interactions within an artificial-reality system according to some embodiments of this disclosure.

FIG. 14B is an illustration of example user interactions within an artificial-reality system according to some embodiments of this disclosure.

FIG. 15A is an illustration of example user interactions within an artificial-reality system according to some embodiments of this disclosure.

FIG. 15B is an illustration of example user interactions within an artificial-reality system according to some embodiments of this disclosure.

FIG. 16 is an illustration of an example wrist-wearable device of an artificial-reality system according to some embodiments of this disclosure.

FIG. 17 is an illustration of an example wearable artificial-reality system according to some embodiments of this disclosure.

FIG. 18 is an illustration of an example augmented-reality system according to some embodiments of this disclosure.

FIG. 19A is an illustration of an example virtual-reality system according to some embodiments of this disclosure.

FIG. 19B is an illustration of another perspective of the virtual-reality systems shown in FIG. 19A.

FIG. 20 is a block diagram showing system components of example artificial- and virtual-reality systems.

Throughout the drawings, identical reference characters and descriptions indicate similar, but not necessarily identical, elements. While the exemplary embodiments described herein are susceptible to various modifications and alternative forms, specific embodiments have been shown by way of example in the drawings and will be described in detail herein. However, the exemplary embodiments described herein are not intended to be limited to the particular forms disclosed. Rather, the present disclosure covers all modifications, equivalents, and alternatives falling within the scope of the appended claims.

### DETAILED DESCRIPTION

As discussed above, this disclosure includes a headset device and electronic system and/or apparatus configured to maintain a display cavity at or below a desired temperature threshold (e.g., 40 degrees Celsius). The headset device may be configured with two physically separate system. For instance, the first system may be a front system worn over the eyes of the user and include display components, image devices, projectors, and the like of the headset device. The second system may be a rear system worn on the back or behind the head of the user and include high temperature components, such as the computing components (e.g., data processors, graphics processors, memory or storage components, and the like). The front system may be communicatively coupled to the rear system via a wired or wireless communication interface. As one example, the front system may be coupled to the rear system via one or more straps or other flexible components.

In some implementations, the front system of the headset device may be equipped with one or more displays and/or optical modules. In some cases, the front system may include two displays or optical modules, one for each eye of the user. In some implementations, the displays may be panels. The front system may be further physically divided via a separator wall into a front cavity and a rear cavity. The front cavity of the front system may include the various electronic components of the front system, such as the image devices, projectors, measurement units (such as vibration sensors, acceleration sensors, gravity sensors, gyroscopes, magnetometer, interrail measurement units, and the like) and the rear cavity of the front system may include the display components, the display drivers, and/or the optical modules (e.g., the right and left optical modules). In this manner and as discussed above, the front system may include an electronics cavity and a display cavity physically divided by the separator wall. In operation, it should be understood that the temperature of the display cavity may be maintained at or below a first desired temperature threshold, while in some cases, the temperature of the electronic cavity may exceed a second desired temperature threshold, the second desired temperature greater than the first desired temperature.

In some implementations, the front system may include a thermal cooling system to assist in maintaining the displays at or below the first desired temperature and the electronics cavity at or below the second desired temperature. For example, the front system may include air inlets along both bottom/side surfaces of the front system and air outlets along the top surface of the headset device. The air inlets may define an opening or provide fluid communication between an exterior of the front system (e.g., open to the surrounding physical environment) and an interior of the display cavity and the outlets may define an opening or provide fluid communication between the exterior of the front system and the interior of the electronics cavity, as discussed herein.

The separator wall between the electronics cavity and the display cavity may be a thermal barrier and formed of a material selected with desired thermal properties. For example, the separator wall may be formed from a hard or soft plastic or rubber. In some cases, the separator wall may be at least partially formed from aluminum and/or magnesium. For instance, the separator wall may have a metallic structure that includes plastic film windows to reduce overall weight of the separator and, thereby, the front system of the headset device.

In some implementations, the separator wall may include one or more blowers that extend into the electronics cavity but are configured to pull air from the display cavity into the electronics cavity. In one specific example, the front system may include two blowers, such as a right blower and a left blower. The right blower and left blower maybe positioned within the electronics cavity and/or the separator wall to pull outside air directly into the display cavity via the inlets. Each of the blowers may further be configured and positioned to exhaust into the electronics cavity to cool the components of the electronics cavity with the air pulled from the display cavity into the electronics cavity. In some cases, other than the blowers the electronics cavity and the display cavity may be sealed with respect to each other, e.g., such that no air passes between the two cavities other than as exhaust air from the blowers. In some cases, each of the blowers may be an ionic fan that may be configured to operate in a quiet or unnoisy manner.

Accordingly, each of the one or more blowers may be positioned such that outside air is pulled into the front system via the inlets along the side/bottom surfaces of the front system. As discussed above, the inlets allow the outside air directly into the display cavity, thereby first cooling the display components. Next, the blower exhausts the air for the display cavity into the electronics cavity to cool the other electronic components of the front system. Finally, the air in the electronics cavity is output from the front system via the outlets along the top surface of the headset device. In this manner, cooler air is used to cool the display components prior to cooling other components of the front system. Further, the airflow may be maintained by the front system in a generally upward direction from the inlets to the outlets.

In some implementations, the display drivers, such as a DDIC, may be positioned within the display cavity while, in other implementations, the DDIC may be positioned in a separate cavity (e.g., the DDIC cavity). In the example in which a separate DDIC cavity is used, a thermal strap may be applied between the display cavity and the DDIC cavity to provided cooling to the DDIC. In another example, the thermal strap may be positioned through or along the separator wall to draw the heat from the DDIC from the DDIC cavity into the electronic cavity. As another example, the DDIC cavity may be sealed from the display cavity but fluidly coupled to the electronics cavity via one or more slots in the separator wall to allow the DDIC to be cooled with the air exhausted from the one or more blowers. In some examples, the DDIC cavity may be formed from a portion of the separator wall or an additional wall that may be, in some instances, formed of magnesium.

In some examples, camera modules or components may be positioned within the front cavity. The camera modules may be coupled to one or more heat sinks that may cause heat to transfer from the camera modules to the front cover or chassis of the headset display to thereby spread the heat generated by the one or more camera modules through the front surface of the headset device. For example, at least a portion of the front cover may be formed of aluminum or other heat spreading/heat sinking material to spread the heat generated by the camera modules through the chassis and at locations away from the face of the user (e.g., such that the heat distribution portions of the chassis or front cover are not in contact with the face of the user when worn).

In some examples, the display panel and/or components may also be equipped with one or more extended heat transfer surfaces. The extended heat transfer surfaces allow the transfer of heat between the outside air and the display panel to be increased, thereby assisting the display panel and/or the display cavity maintaining a temperature at or below the display cavity temperature threshold (e.g., 40 degrees Celsius).

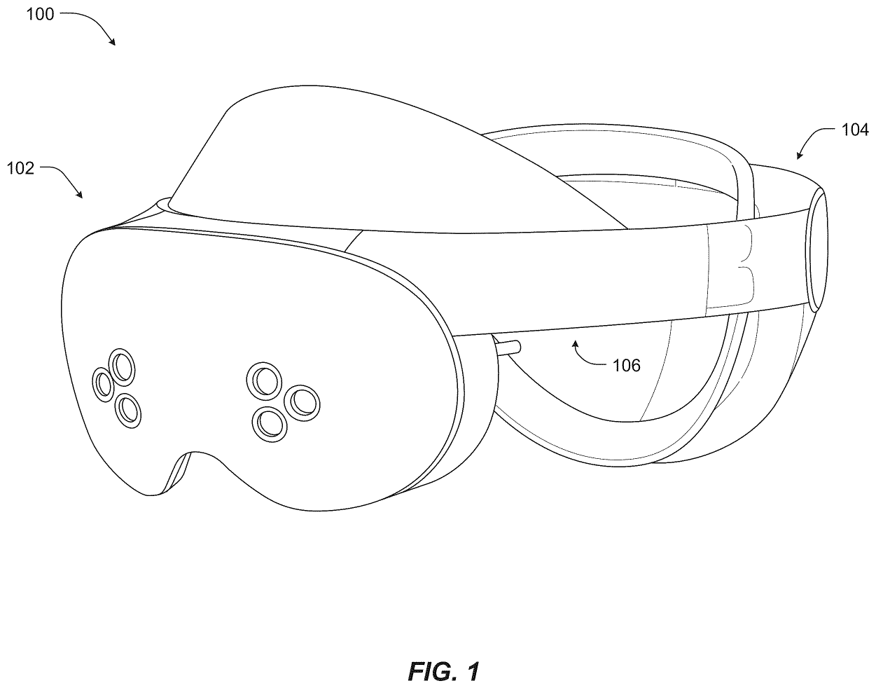

FIG. 1 is an example perspective view of an example electronic display system 100 comprising a front system 102 and a rear system 104, in accordance with one or more examples. As illustrated, the electronic display system 100 is a headset device that is configured to provide a virtual reality, mixed reality or otherwise immersive viewing experience for a user. In this example, the front system 102 may be configured to be worn over the eyes of the user and includes display components, image devices, projectors, and the like. The rear system 104 is configured to be worn on the back or behind the head of the user and includes various computing components (e.g., data processors, graphics processors, memory or storage components, and the like. In this manner, the components that operate at higher temperature may be physically separated from the display components of the front system 102, thereby assisting the system 100 in maintaining the display panels and optical modules at or below a desired temperature.

In the illustrated example, the front system 102 may be adjustably coupled to the rear system 104 via one or more straps 106. In some cases, the straps 106 may be adjustable to conform to differing head sizes of the various users. The straps 106 may also be equipped with one or more components to facilitate communication between the components of the front system 102 and the components of the rear system 104. For instance, the straps 106 may facilitate wired communication between the components of the front system 102 and the components of the rear system 104. In other examples, the components of the front system 102 and the components of the rear system 104 may be configured to communicate via one or more wireless communication interfaces and/or channels.

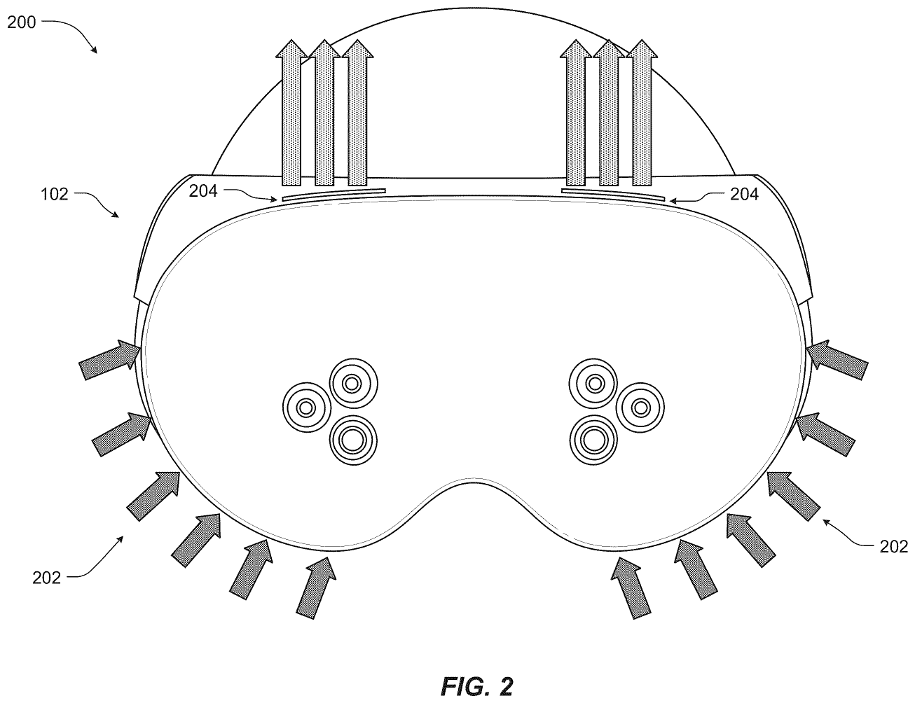

FIG. 2 is an example side and front view 200 of the front system 102 of an electronic display system 100 of FIG. 1 having inlets 202 and outlets 204, in accordance with one or more examples. As discussed herein, the front system 102 may include display components that are configured to maintain a temperature at or below a first desired temperature as well as other components that are configured to maintain a temperature at or below a second desired temperature. In various implementations, the display components are contained in a display cavity and the other components are contained in an electronics cavity. As discussed herein, the display cavity may be physically sealed or separated from the electronics cavity by a thermal separator wall. The two cavities may also be in fluid communication via blower that is configured to pull air from the display cavity and exhaust the air into the electronics cavity.

In the current example, the front system 102 is formed by a housing that has a top surface and a bottom surface, the housing comprising an electronics cavity separated from a display cavity by a separator wall, as discussed herein. In the illustrated example, the inlets 202 along the bottom portion of the housing of the front system 102 are open to or in fluid communication with the display cavity. In general, the inlets 202 may be positioned along a bottom surface and/or side surface of the front system 102. For example, the inlets 202 may be positioned in the lower two thirds of the side surface and/or along the bottom surface. In this example, the inlets 202 may allow outside air to flow into the display cavity from substantially an area of the environment along the bottom surface of the front system 102.

The outlets 204 along the top portion of the housing of the front system 102 are open to or in fluid communication with the electronics cavity. In general, the outlets 204 may be positioned along a top surface and/or side surface of the front system 102. For example, the outlets 204 may be positioned in the upper one third of the side surface and/or along the top surface. In this example, the outlets 204 may allow internal air to flow out of the electronics cavity at an area substantially along the top surface of the front system 102.

As configured, the inlets 202 and outlets 204 allow for a substantially upward flow of air within the front system 102. For example, the air may flow into the inlets 202, upward through the display cavity, into the electronics cavity via the blower, upward through the electronics.

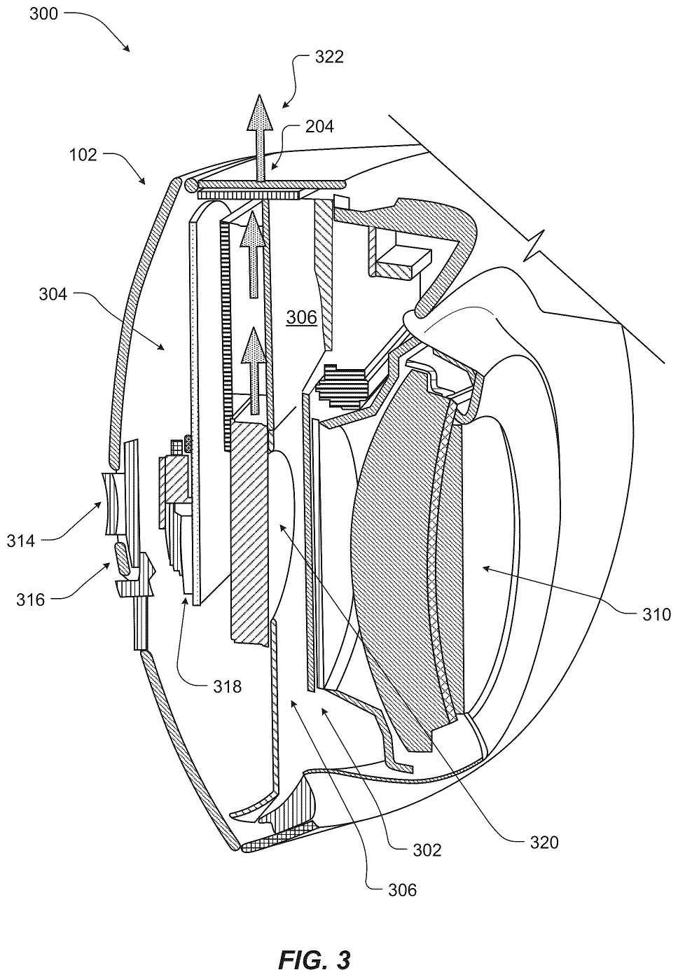

FIG. 3 is an example side view 300 of an example front system 102 of an electronic display system 100 utilizing multiple blowers 320, in accordance with one or more examples. As shown, the front system 102 is divided into a display cavity 302 and an electronics cavity 304 via a separator wall 306. As discussed above, the display cavity 302 may include one or more display panel(s) 308 and one or more optical module(s) 310. The electronics cavity 304 may include other components such as example components including cameras or image device 314, projectors 316, circuit boards 318, and the like.

As illustrated one or more separator walls 306 may substantially vertically divide the display cavity 302 from the electronics cavity 304. However, the separator walls 306 may not extend fully from the top surface of the front system 102 to the bottom surface. In this example, the inlets are in fluid communication with the display cavity 302 and the outlets 204 are shown in fluid communication with the electronics cavity 304. As illustrated, the blowers 320 are positioned substantially within the electronics cavity 304 and configured to pull air from the display cavity 302 and exhaust the air into the electronics cavity 304. In this manner, the heat generated by a motor of the blowers 320 is contained within the electronics cavity 304 while allowing the blowers 320 to pull air from the display cavity 302. Accordingly, outside air is pulled into the display cavity 302 via the inlets to cool the display components (e.g., the one or more display panel(s) 308, the one or more optical module(s) 310, the display diver, and the like). The blowers 320 then pull the air from the display cavity 302 into the electronics cavity 304 to cool the other electronic components (e.g., the cameras or image device 314, the projectors 316, the circuit boards 318, and the like). The air is then expulsed from the electronics cavity 304 via the outlets 204 along the top surface of the front system 102. In the current example the air 322 exhausted by the blowers 320 may be pressurized to cause the exhausted air to achieve better circulation particularly with respect to the finer structures and components of the display cavity 304.

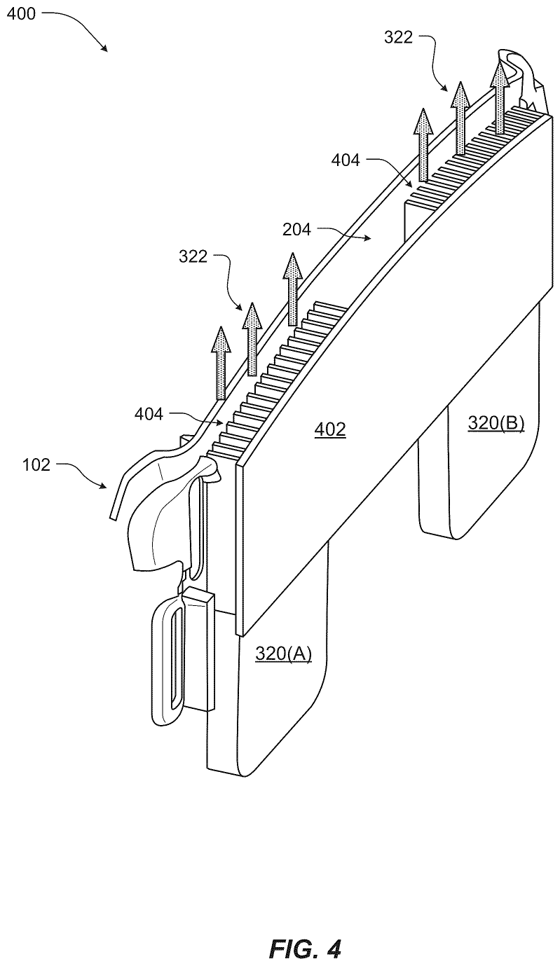

FIG. 4 is an example view 400 of the example portion of the front system 102 of FIG. 1, in accordance with one or more examples. In the current example, two blowers 320(A) and 320(B) are illustrated. In this example, each of the blowers 320 align with an optical module (not shown) and an eye of the user. For instance, the front system 102 includes a right blower 320(A) and a left blower 320(B) that may be, respectfully, associated with right eye display components and left eye display components. In this manner, each of blowers 320 may direct air through the display cavity and exhaust air into the electronics cavity providing two areas of fluid communication through the separator wall and between the two cavities of the front system 102.

In the current example, the separator wall may include or be formed via, at least in part, a vapor chamber 402. Air 322 is configured to be exhausted from the outlets 204 along a top surface of the front system 102 past the vapor chamber. In this manner, the air 322 may be pulled into the display chamber (e.g., the back chamber) via the inlets substantially along the bottom side surface of the front system 102 and into the blowers 320 which push the air 322 out through the electronics cavity (e.g., the front cavity) and out past the vapor chamber 402 and the outlets 204. In the current example, the outlets 204 adjacent the vapor chamber 402 include fins 404 that may act as a heat sink or structure to cool the air 322 as the air 322 is exhausted from the front system 102, thereby cooling the main circuit board and/or other electronic components in the electronics cavity.

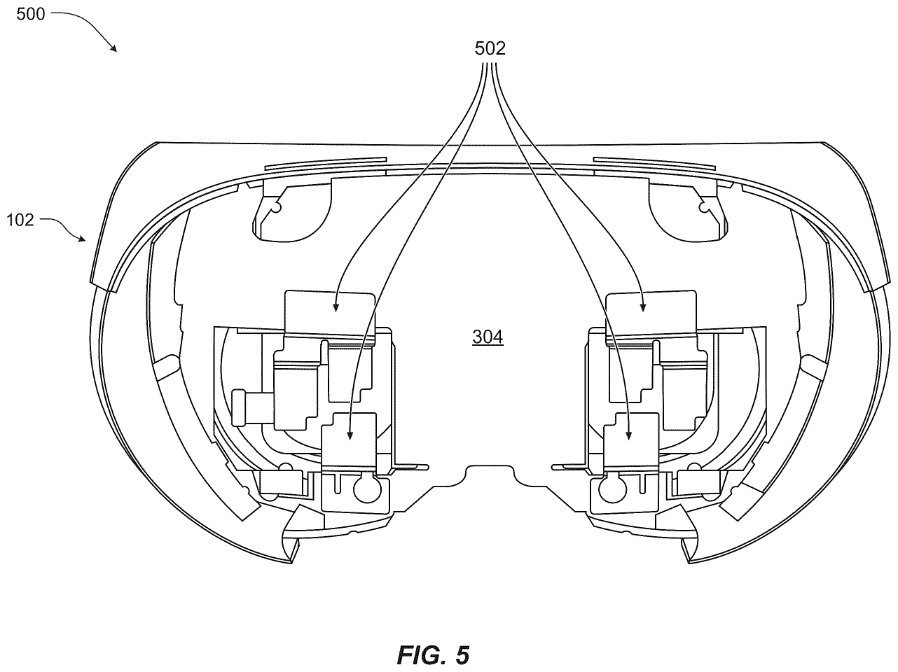

FIG. 5 is an example cross-sectional top view 500 of an example front system 102 of an electronic display system of FIG. 1, in accordance with one or more examples. In the illustrated example, a portion of the electronics cavity 304 of the front system 102 is shown. In the current example, heat sinks 502 may be coupled to the camera modules of the front camera or image devices to the front cover or front chassis of the display system 102. In this example, the heat sinks 502 may cause heat generated by one or more camera modules to be dissipated and spread over at least a portion of the front cover of the display system 102.

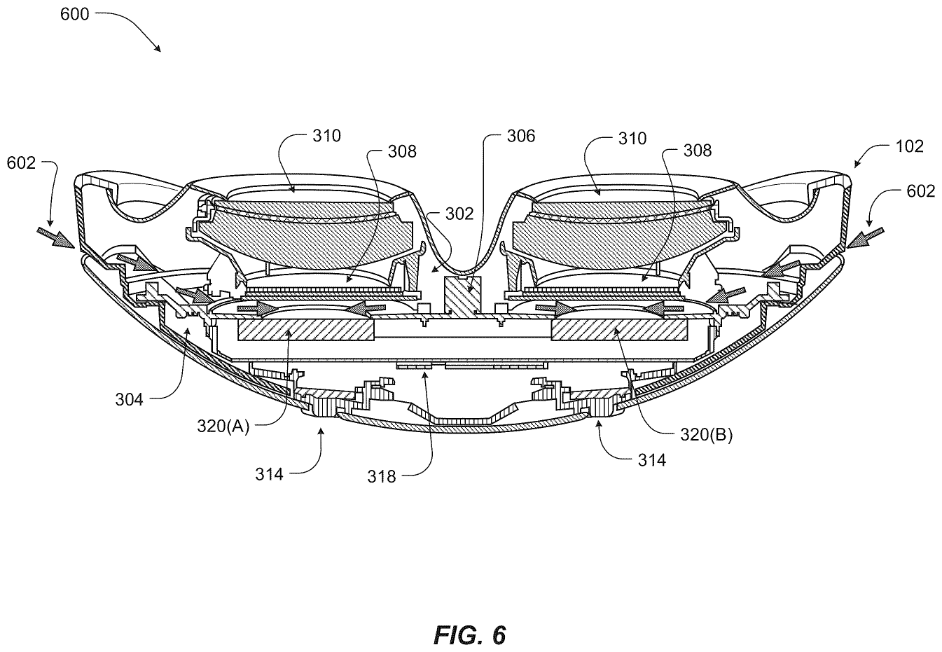

FIG. 6 is an example cross-sectional top view 600 of an example front system 102 of an electronic display system of FIG. 1, in accordance with one or more examples. As shown, the front system 102 is divided into a display cavity 302 and an electronics cavity 304 via a separator wall 306. As discussed above, the display cavity 302 may include one or more display panel(s) 308, one or more optical module(s) 310, and the like. The electronics cavity 304 may include other components such as example components including cameras or image device 314, projectors, circuit boards 318, other components, and the like.

As illustrated the separator wall 306 may substantially vertically and horizontally divide the display cavity 302 from the electronics cavity 304. In the current example, the separator wall 306 may extend substantially from the left surface of the front system 102 to the right surface of the front system 102, as shown. As illustrated, a first blower 320(A) and a second blower 320(B) are positioned substantially within the electronics cavity 304 and in line with the display panels 308 and the optical modules 310. The blowers 320 may be configured to pull external air 602 through the display cavity 302 and exhaust into the electronics cavity 304. The air 602 may then cool the display components in the display cavity 302 as well as a portion of the chassis in contact with the face of the user when worn or during use. In some cases, the exhausted air may be pressurized, as discussed herein.

As discussed above, the heat generated by a motor of the blowers 320 is contained within the electronics cavity 304 while allowing the blowers 320 to pull air from the display cavity 302. In some cases, the blowers 320 may be ionic fans to reduce the noise of the headset display system during use. In the current example, the separator wall 306 may also extend to divide the display cavity 302 into a right and a left portion, such that each portion is associated with one of the blowers 320(A) and 320(B) as shown. In some cases, each of the blowers 320(A) and 320(B) may be of dimensions including 30 millimeters wide by 30 millimeters tall and 5 millimeters wide (e.g., from the front side opposite the face of the suer to the back side in contact with the face of the user of the display system). In another example, each of the blowers 320(A) and 320(B) May be of dimensions including between 25 millimeters and 35 millimeters wide by 25 millimeters and 35 millimeters tall and 2 millimeters and 7 millimeters wide.

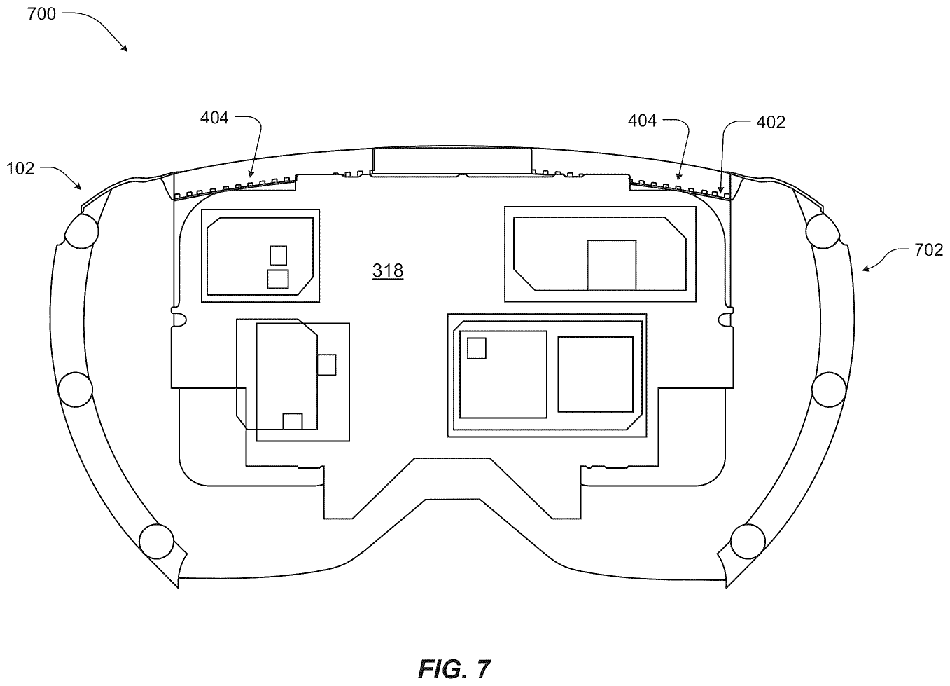

FIG. 7 is an example cross-sectional side view 700 of an example front system 102 of an electronic display system 100, in accordance with one or more examples. In the current example, a circuit board 318 of the electronics cavity of the front system 102 is shown. The circuit board 318 may be in physical contact with the vapor chamber 402, such that the vapor chamber 402 is positioned adjacent to and behind (e.g., closer to the eyes of the user) than the circuit board 318. In some examples, the vapor chamber 402 may also be in physical contact or connectivity with a chassis 702 of the front system 102, such that heat may be captured by, for instance, the fins 404 of the vapor chamber 402, and spread or dissipated via the chassis 702 and/or at least a portion of the front cover not in contact with the skin of the user when worn. In this manner, the vapor chamber 402, the chassis 702, and portions of the front cover may be used to dissipate heat of the circuit board 318 when in use. In some cases, the circuit board 318 may be a main processing board of the display system 100.

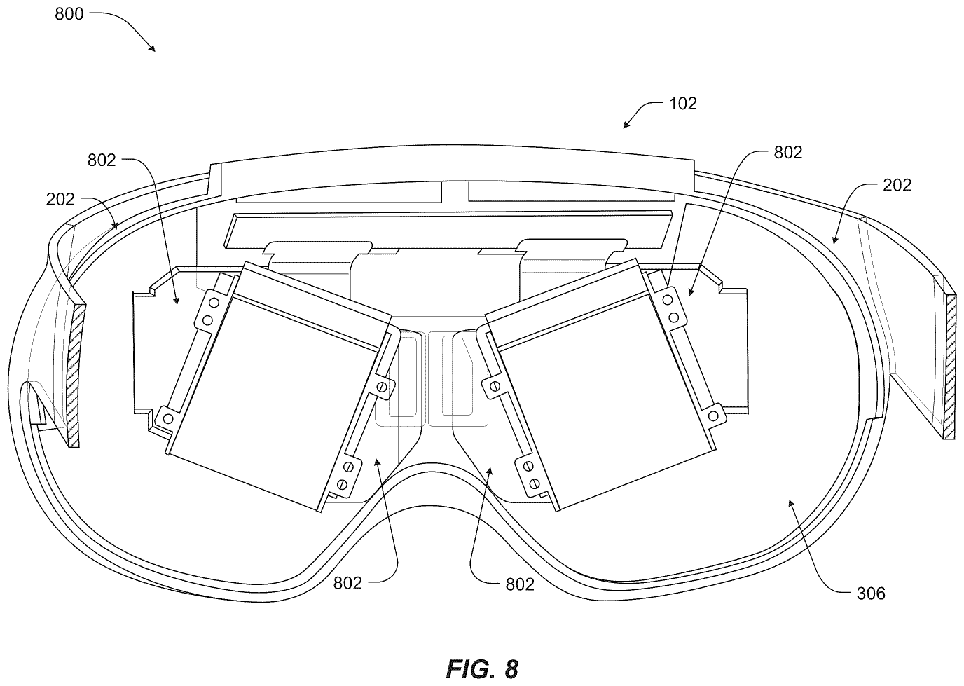

FIG. 8 is another example 800 cross-sectional side view of an example front system 102 of an electronic display system 100 of FIG. 1, in accordance with one or more examples. In this example, the outside air may enter the display cavity via the inlets 202 along the side surfaces of the front system 102 to cool the display components. The air may pass through the plenums 802 into the electronics cavity to cool the other electronic components. The air is then expulsed from the electronics cavity via the outlets 204 along the top surface of the front system 102.

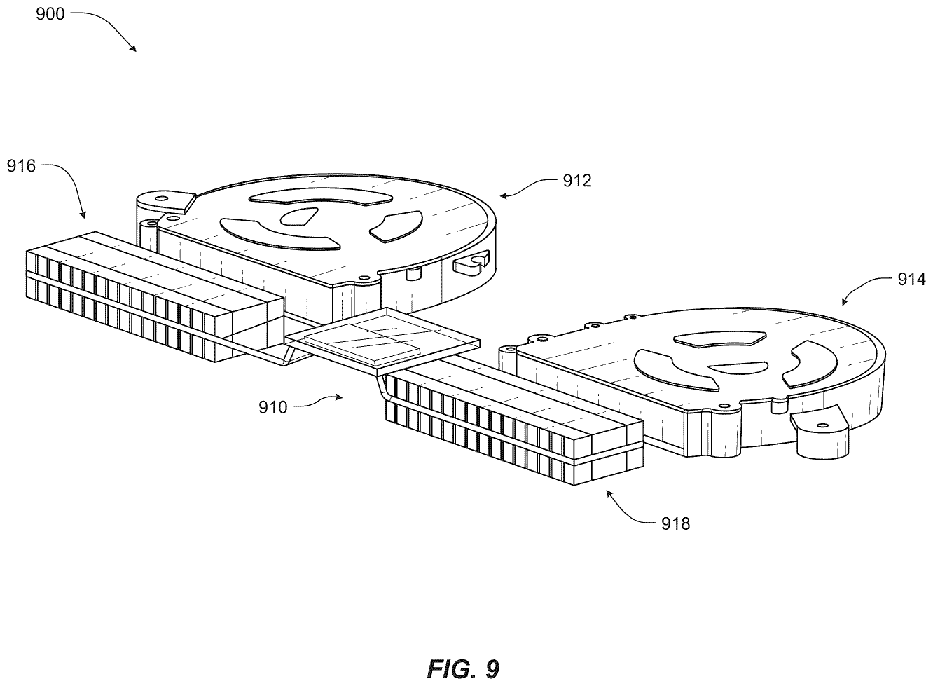

FIG. 9 is a perspective view of a heat dissipation system 900 including a heat pipe 910, in accordance with one or more examples. In this example, the heat pipe 910 may be thermally coupled to a microchip of a head-mounted display system. In the current example, the housing of the front system 102 may include an electronics cavity containing the microchip (e.g., further including system-on-a-chip and/or a memory chip) and a display cavity containing a display screen. In further examples, the housing may include a head-mounted display housing.

In some examples, the heat pipe 910 may be positioned at least partially within the electronics cavity. In some examples, the heat pipe 910 may be configured to cool the microchip of the head-mounted display system. In some examples, the heat pipe 910 may be positioned adjacent to at least one fan, such as a first fan 912 and a second fan 914. For example, each of the first fan 912 and the second fan 914 may be include fan blades, an ionic fan, or other mechanism to move air. At least one heat dissipation fin, such as a first heat dissipation fin 916 and a second heat dissipation fin 918 may be coupled to the heat pipe 910 to dissipate heat from the heat pipe 910. For example, the first fan 912 may direct air across the first heat dissipation fin 916 and the second fan 914 may direct air across the second heat dissipation fin 918.

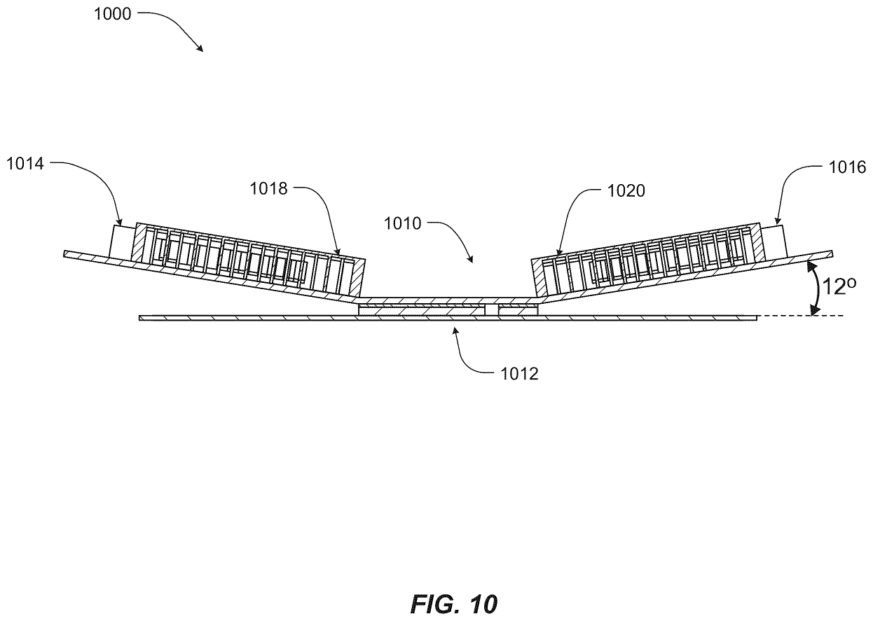

Turning to FIG. 10, a top view of a heat dissipation system 1000 including a heat pipe 1010 is shown with an alternative configuration (e.g., curved or angled orientation), in accordance with one or more examples. The heat pipe 1010 may include and/or represent various configurations to have any suitable orientation for integration with the head-mounted display system. For example, a central region of the heat pipe 1010 may be coupled to a microchip 1012 to cool the microchip 1012. End regions of the heat pipe 1010 may be angled upward (e.g., from the view of FIG. 10) away from the central region, such as at an angle between 5 and 20 degrees, such as about 10 degrees, about 12 degrees (as illustrated in FIG. 10), about 15 degrees, etc. Heat dissipation fins 1018 and 1020 may be respectively coupled to the end regions of the heat pipe 1010 to withdraw heat from the heat pipe 1010. Additionally, in some examples, the fans 1014, 1016 may respectively force air across the heat dissipation fins 1018, 1020 for further heat removal.

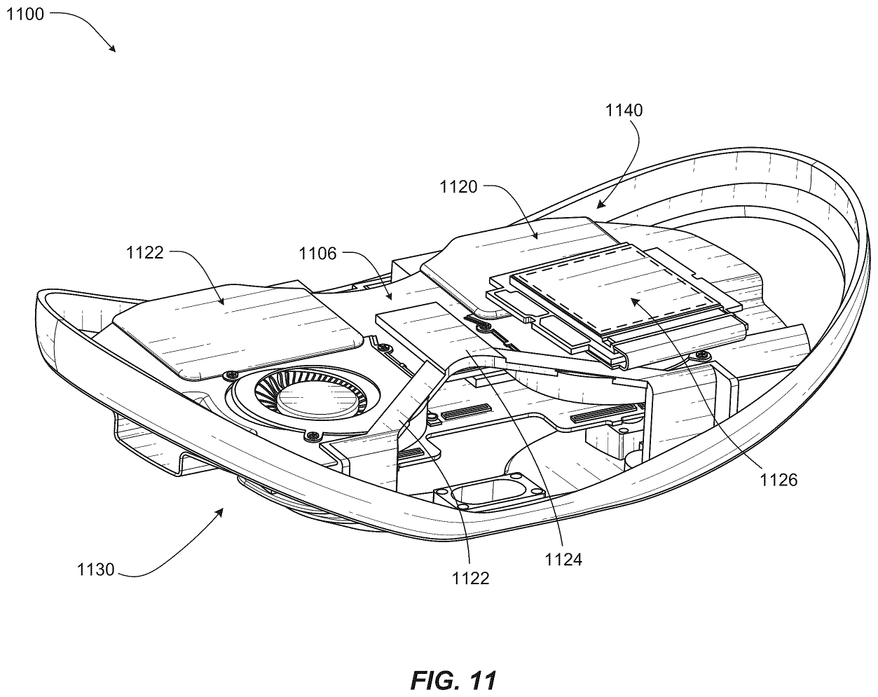

FIG. 11 illustrates a perspective view of a display assembly 1100 including a separator wall 1106 positioned in an electronics display system, in accordance with one or more examples. In this example, the separator wall 1106 may separate an electronics cavity 1130 from a display cavity 1140. In some examples, the separator wall 1106 may be positioned directly between a heat sink and one or more display screens 1126 (one shown in FIG. 11, with another not shown to better view underlying features). In some examples, the separator wall 1106 may include a thermally insulating material. For example, the separator wall 1106 may be formed from a variety of different thermally insulating materials, including, without limitation silicon materials, glass materials, ceramic materials, carbon fiber materials, polymer materials, plastic materials, textiles, fabrics, or any combination thereof. In some examples, the separator wall 1106 may be formed to include a first air gap 1120 and a second air gap 1122 (e.g., insulating gaps). In some examples, the seperator wall 1106 may include and/or represent a dual-wall insulating structure defining the first and the second air gaps 1120 and 1122. The dual-wall insulating structure and the first and the second air gaps 1120 and 1122 may be positioned between (e.g., directly between) portions of the heat sink and the display screen(s) to reduce an amount of heat moving from the heat sink to the display screen(s).

In some examples, each of the first and the second air gaps 1120, 1122 may have a thickness of 0.5 mm to 10 mm. In some examples, the thickness may be in a range of 0.5 mm to 9 mm, 0.5 mm to 8 mm, 0.5 mm to 7 mm, 0.5 mm to 6 mm, 0.5 mm to 5 mm, 0.5 mm to 4 mm, 0.5 mm to 3 mm, 0.5 mm to 2 mm, 0.5 mm to 1 mm, 0.5 mm to 10 mm, 1 mm to 10 mm, 2 mm to 10 mm, 3 mm to 10 mm, 4 mm to 10 mm, 5 mm to 10 mm, 6 mm to 10 mm, 7 mm to 10 mm, 8 mm to 10 mm, 9 mm to 10 mm, or 9.5 mm to 10 mm.

In the current example, the housing of front system 102 may include an electronics cavity including a microchip and a display cavity including a near-eye display screen. Additionally, a heat sink within the electronics cavity may be thermally coupled to the microchip and configured to draw heat from the microchip. In some examples, the dual-wall insulating structure of the separator wall 1106 may include a first polymer wall adjacent to the heat sink and a second polymer wall separated from the first polymer wall by the first and second air gaps 1120, 1122, respectively. In further examples, the second polymer wall may be adjacent to the near-eye display screen. In other examples, the near-eye display screen may include a first near-eye display screen positioned to display images to a user's right eye and a second near-eye display screen positioned to display images to a user's left eye. In some examples, the microchip may be positioned centrally between the first near-eye display screen and the second near-eye display screen. In some examples, fans (e.g., bladed fans or ionic fans) may be coupled to the separator wall 1106 and may extend into the electronics cavity.

In some examples, the separator wall 1106 may include and/or represent a different form configured to improve the heat dissipation within the display assembly 1100. For example, the separator wall 1106 may include with a Y-shaped portion 1122, formed with a heat-conductive material (e.g., aluminum) to dissipate heat away from the display screens of the display system assembly 1100. In further examples, the separator wall 1106 may further include a heat defusal plate 1124 that may be formed with a non-heat conductive material (e.g., plastic). The heat defusal plate 1124 may create a heat insulation area within the display assembly 1100, further improving the heat dissipation within the display assembly 1100.

Embodiments of the present disclosure may include or be implemented in conjunction with various types of Artificial-Reality (AR) systems. AR may be any superimposed functionality and/or sensory-detectable content presented by an artificial-reality system within a user's physical surroundings. In other words, AR is a form of reality that has been adjusted in some manner before presentation to a user. AR can include and/or represent virtual reality (VR), augmented reality, mixed AR (MAR), or some combination and/or variation of these types of realities. Similarly, AR environments may include VR environments (including non-immersive, semi-immersive, and fully immersive VR environments), augmented-reality environments (including marker-based augmented-reality environments, markerless augmented-reality environments, location-based augmented-reality environments, and projection-based augmented-reality environments), hybrid-reality environments, and/or any other type or form of mixed- or alternative-reality environments.

AR content may include completely computer-generated content or computer-generated content combined with captured (e.g., real-world) content. Such AR content may include video, audio, haptic feedback, or some combination thereof, any of which may be presented in a single channel or in multiple channels (such as stereo video that produces a three-dimensional (3D) effect to the viewer). Additionally, in some embodiments, AR may also be associated with applications, products, accessories, services, or some combination thereof, that are used to, for example, create content in an artificial reality and/or are otherwise used in (e.g., to perform activities in) an artificial reality.

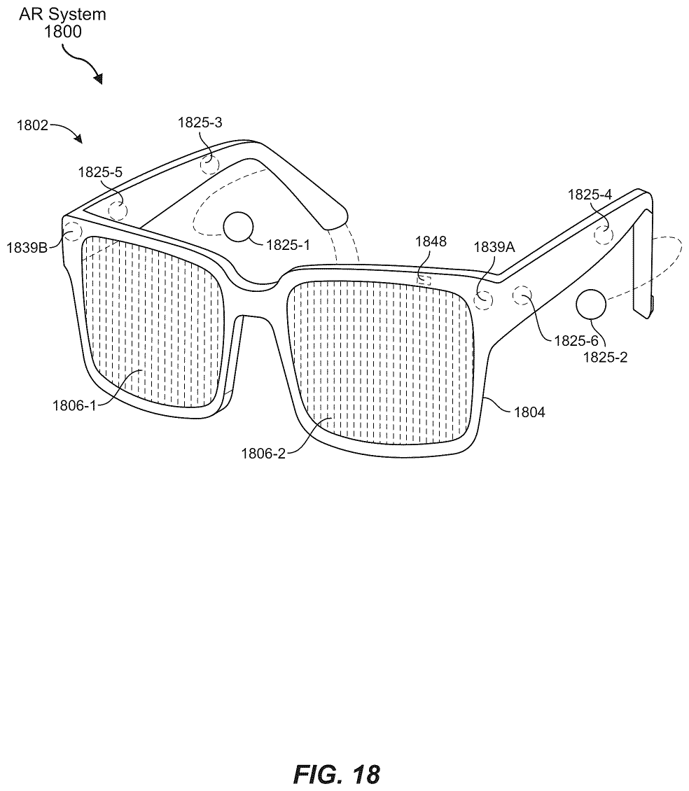

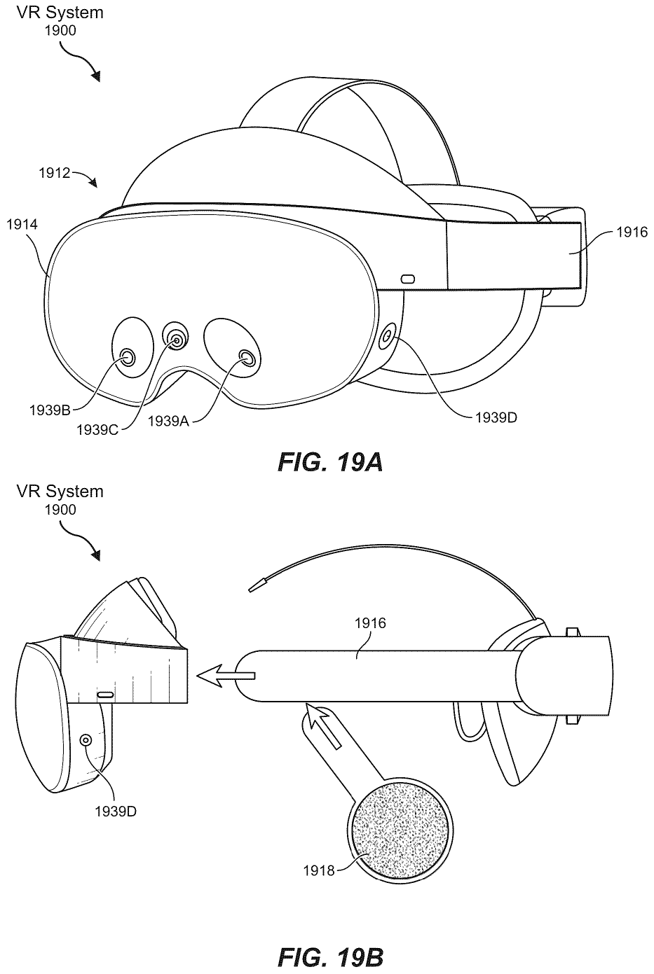

AR systems may be implemented in a variety of different form factors and configurations. Some AR systems may be designed to work without near-eye displays (NEDs). Other AR systems may include a NED that also provides visibility into the real world (such as, e.g., augmented-reality system 1800 in FIG. 18) or that visually immerses a user in an artificial reality (such as, e.g., virtual-reality system 1900 in FIGS. 19A and 19B). While some AR devices may be self-contained systems, other AR devices may communicate and/or coordinate with external devices to provide an AR experience to a user. Examples of such external devices include handheld controllers, mobile devices, desktop computers, devices worn by a user, devices worn by one or more other users, and/or any other suitable external system.

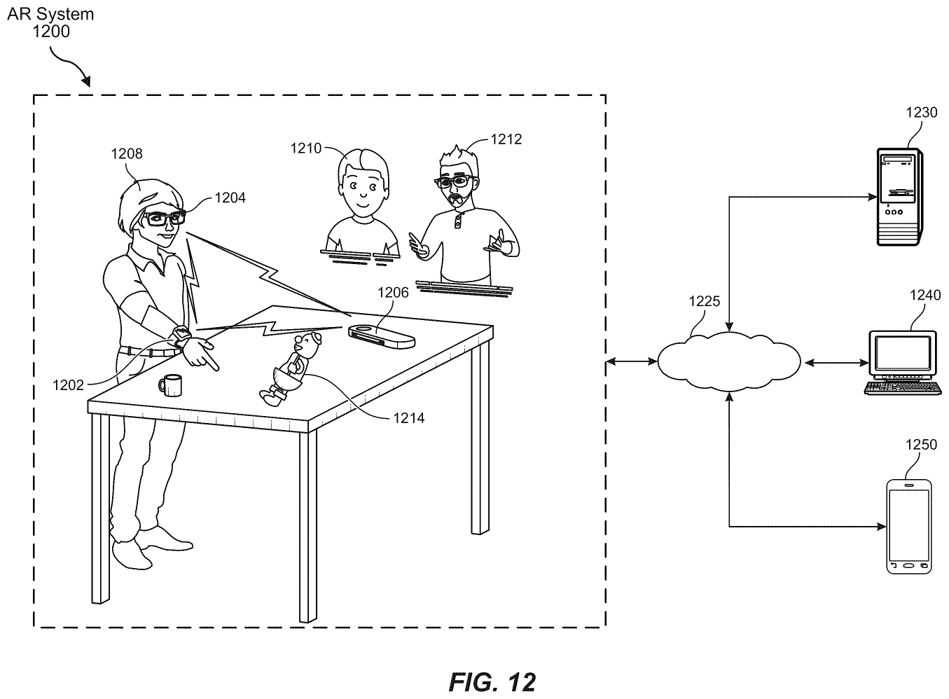

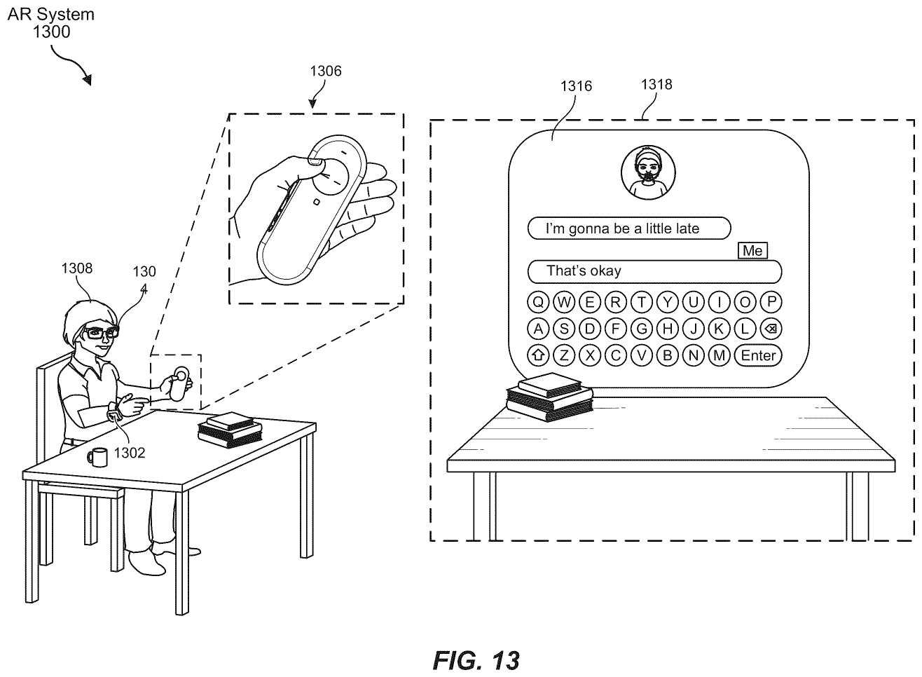

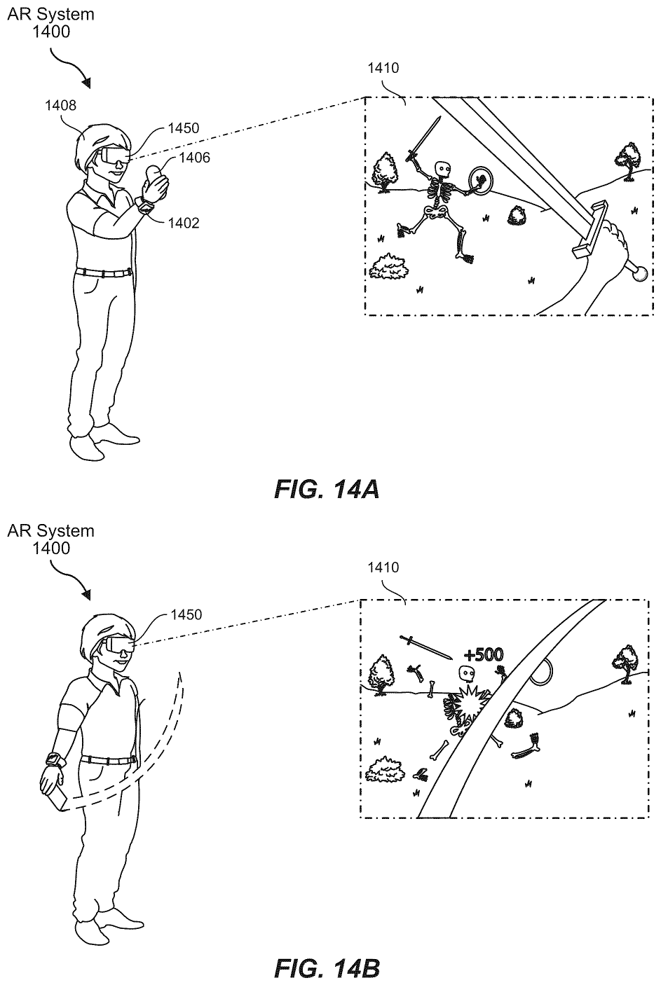

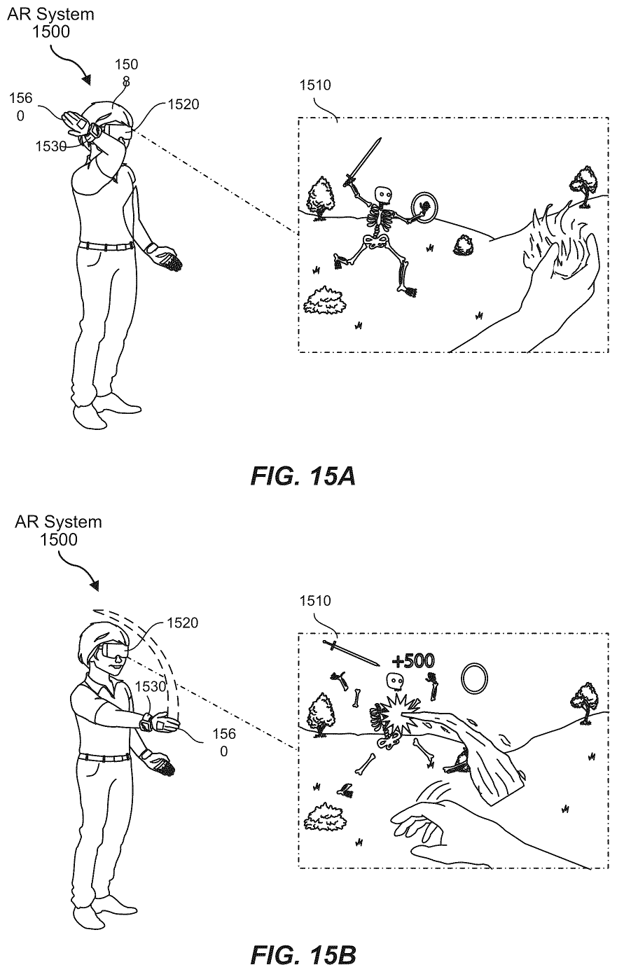

FIGS. 12-15B illustrate example artificial-reality (AR) systems in accordance with some embodiments. FIG. 12 shows a first AR system 1200 and first example user interactions using a wrist-wearable device 1202, a head-wearable device (e.g., AR glasses 1800), and/or a handheld intermediary processing device (HIPD) 1206. FIG. 13 shows a second AR system 1300 and second example user interactions using a wrist-wearable device 1302, AR glasses 1304, and/or an HIPD 1306. FIGS. 14A and 14B show a third AR system 1400 and third example user 1408 interactions using a wrist-wearable device 1402, a head-wearable device (e.g., VR headset 1450), and/or an HIPD 1406. FIGS. 15A and 15B show a fourth AR system 1500 and fourth example user 1508 interactions using a wrist-wearable device 1530, VR headset 1520, and/or a haptic device 1560 (e.g., wearable gloves).

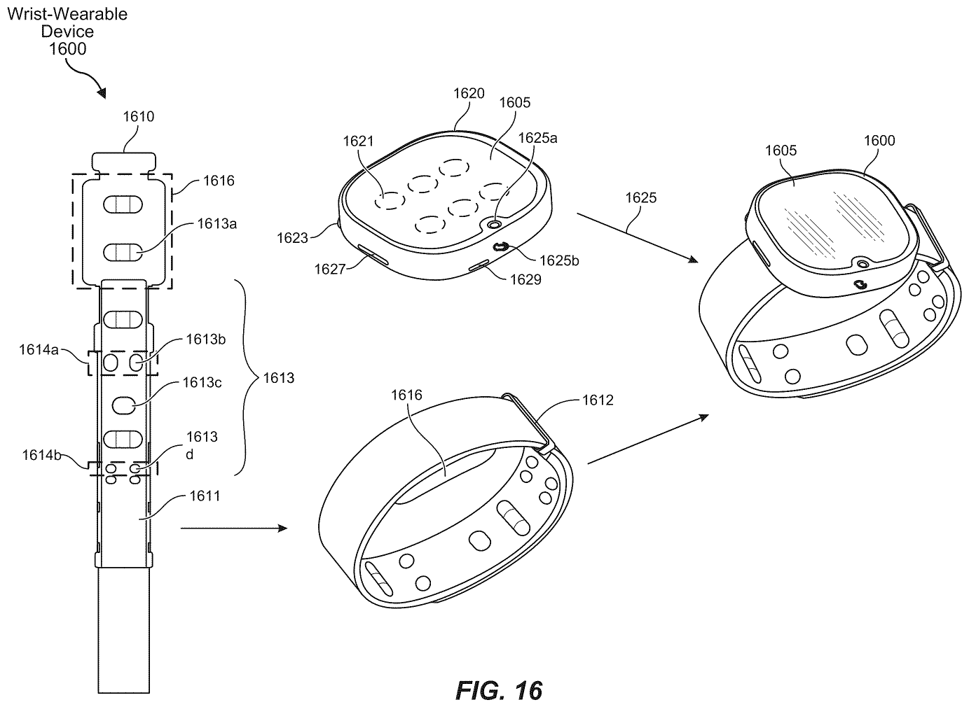

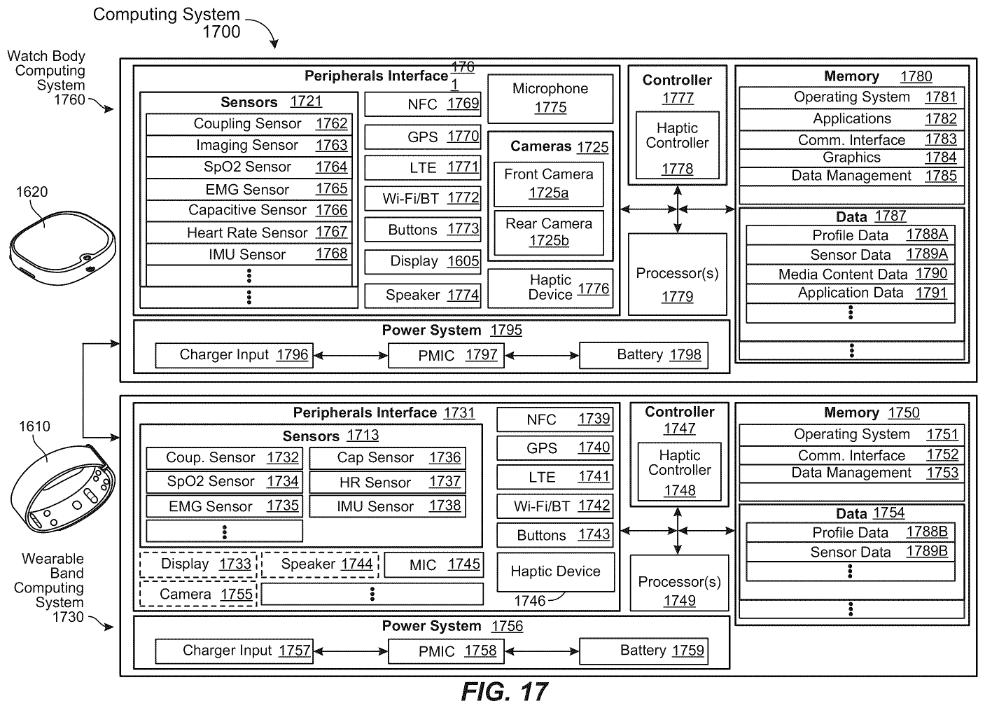

A wrist-wearable device 1600, which can be used for wrist-wearable device 1202, 1302, 1402, 1530, and one or more of its components, are described below in reference to FIGS. 16 and 17; head-wearable devices 1800 and 1900, which can respectively be used for AR glasses 1204, 1304 or VR headset 1450, 1520, and their one or more components are described below in reference to FIGS. 18-20.

Referring to FIG. 12, wrist-wearable device 1202, AR glasses 1204, and/or HIPD 1206 can communicatively couple via a network 1225 (e.g., cellular, near field, Wi-Fi, personal area network, wireless LAN, etc.). Additionally, wrist-wearable device 1202, AR glasses 1204, and/or HIPD 1206 can also communicatively couple with one or more servers 1230, computers 1240 (e.g., laptops, computers, etc.), mobile devices 1250 (e.g., smartphones, tablets, etc.), and/or other electronic devices via network 1225 (e.g., cellular, near field, Wi-Fi, personal area network, wireless LAN, etc.).

In FIG. 12, a user 1208 is shown wearing wrist-wearable device 1202 and AR glasses 1204 and having HIPD 1206 on their desk. The wrist-wearable device 1202, AR glasses 1204, and HIPD 1206 facilitate user interaction with an AR environment. In particular, as shown by first AR system 1200, wrist-wearable device 1202, AR glasses 1204, and/or HIPD 1206 cause presentation of one or more avatars 1210, digital representations of contacts 1212, and virtual objects 1214. As discussed below, user 1208 can interact with one or more avatars 1210, digital representations of contacts 1212, and virtual objects 1214 via wrist-wearable device 1202, AR glasses 1204, and/or HIPD 1206.

User 1208 can use any of wrist-wearable device 1202, AR glasses 1204, and/or HIPD 1206 to provide user inputs. For example, user 1208 can perform one or more hand gestures that are detected by wrist-wearable device 1202 (e.g., using one or more EMG sensors and/or IMUs, described below in reference to FIGS. 16 and 17) and/or AR glasses 1204 (e.g., using one or more image sensor or camera, described below in reference to FIGS. 18-10) to provide a user input. Alternatively, or additionally, user 1208 can provide a user input via one or more touch surfaces of wrist-wearable device 1202, AR glasses 1204, HIPD 1206, and/or voice commands captured by a microphone of wrist-wearable device 1202, AR glasses 1204, and/or HIPD 1206. In some embodiments, wrist-wearable device 1202, AR glasses 1204, and/or HIPD 1206 include a digital assistant to help user 1208 in providing a user input (e.g., completing a sequence of operations, suggesting different operations or commands, providing reminders, confirming a command, etc.). In some embodiments, user 1208 can provide a user input via one or more facial gestures and/or facial expressions. For example, cameras of wrist-wearable device 1202, AR glasses 1204, and/or HIPD 1206 can track eyes of user 1208 for navigating a user interface.

Wrist-wearable device 1202, AR glasses 1204, and/or HIPD 1206 can operate alone or in conjunction to allow user 1208 to interact with the AR environment. In some embodiments, HIPD 1206 is configured to operate as a central hub or control center for the wrist-wearable device 1202, AR glasses 1204, and/or another communicatively coupled device. For example, user 1208 can provide an input to interact with the AR environment at any of wrist-wearable device 1202, AR glasses 1204, and/or HIPD 1206, and HIPD 1206 can identify one or more back-end and front-end tasks to cause the performance of the requested interaction and distribute instructions to cause the performance of the one or more back-end and front-end tasks at wrist-wearable device 1202, AR glasses 1204, and/or HIPD 1206. In some embodiments, a back-end task is a background processing task that is not perceptible by the user (e.g., rendering content, decompression, compression, etc.), and a front-end task is a user-facing task that is perceptible to the user (e.g., presenting information to the user, providing feedback to the user, etc.). HIPD 1206 can perform the back-end tasks and provide wrist-wearable device 1202 and/or AR glasses 1204 operational data corresponding to the performed back-end tasks such that wrist-wearable device 1202 and/or AR glasses 1204 can perform the front-end tasks. In this way, HIPD 1206, which has more computational resources and greater thermal headroom than wrist-wearable device 1202 and/or AR glasses 1204, performs computationally intensive tasks and reduces the computer resource utilization and/or power usage of wrist-wearable device 1202 and/or AR glasses 1204.

In the example shown by first AR system 1200, HIPD 1206 identifies one or more back-end tasks and front-end tasks associated with a user request to initiate an AR video call with one or more other users (represented by avatar 1210 and the digital representation of contact 1212) and distributes instructions to cause the performance of the one or more back-end tasks and front-end tasks. In particular, HIPD 1206 performs back-end tasks for processing and/or rendering image data (and other data) associated with the AR video call and provides operational data associated with the performed back-end tasks to AR glasses 1204 such that the AR glasses 1204 perform front-end tasks for presenting the AR video call (e.g., presenting avatar 1210 and digital representation of contact 1212).

In some embodiments, HIPD 1206 can operate as a focal or anchor point for causing the presentation of information. This allows user 1208 to be generally aware of where information is presented. For example, as shown in first AR system 1200, avatar 1210 and the digital representation of contact 1212 are presented above HIPD 1206. In particular, HIPD 1206 and AR glasses 1204 operate in conjunction to determine a location for presenting avatar 1210 and the digital representation of contact 1212. In some embodiments, information can be presented a predetermined distance from HIPD 1206 (e.g., within 5 meters). For example, as shown in first AR system 1200, virtual object 1214 is presented on the desk some distance from HIPD 1206. Similar to the above example, HIPD 1206 and AR glasses 1204 can operate in conjunction to determine a location for presenting virtual object 1214. Alternatively, in some embodiments, presentation of information is not bound by HIPD 1206. More specifically, avatar 1210, digital representation of contact 1212, and virtual object 1214 do not have to be presented within a predetermined distance of HIPD 1206.

User inputs provided at wrist-wearable device 1202, AR glasses 1204, and/or HIPD 1206 are coordinated such that the user can use any device to initiate, continue, and/or complete an operation. For example, user 1208 can provide a user input to AR glasses 1204 to cause AR glasses 1204 to present virtual object 1214 and, while virtual object 1214 is presented by AR glasses 1204, user 1208 can provide one or more hand gestures via wrist-wearable device 1202 to interact and/or manipulate virtual object 1214.

FIG. 13 shows a user 1308 wearing a wrist-wearable device 1302 and AR glasses 1304, and holding an HIPD 1306. In second AR system 1300, the wrist-wearable device 1302, AR glasses 1304, and/or HIPD 1306 are used to receive and/or provide one or more messages to a contact of user 1308. In particular, wrist-wearable device 1302, AR glasses 1304, and/or HIPD 1306 detect and coordinate one or more user inputs to initiate a messaging application and prepare a response to a received message via the messaging application.

In some embodiments, user 1308 initiates, via a user input, an application on wrist-wearable device 1302, AR glasses 1304, and/or HIPD 1306 that causes the application to initiate on at least one device. For example, in second AR system 1300, user 1308 performs a hand gesture associated with a command for initiating a messaging application (represented by messaging user interface 1316), wrist-wearable device 1302 detects the hand gesture and, based on a determination that user 1308 is wearing AR glasses 1304, causes AR glasses 1304 to present a messaging user interface 1316 of the messaging application. AR glasses 1304 can present messaging user interface 1316 to user 1308 via its display (e.g., as shown by a field of view 1318 of user 1308). In some embodiments, the application is initiated and executed on the device (e.g., wrist-wearable device 1302, AR glasses 1304, and/or HIPD 1306) that detects the user input to initiate the application, and the device provides another device operational data to cause the presentation of the messaging application. For example, wrist-wearable device 1302 can detect the user input to initiate a messaging application, initiate and run the messaging application, and provide operational data to AR glasses 1304 and/or HIPD 1306 to cause presentation of the messaging application. Alternatively, the application can be initiated and executed at a device other than the device that detected the user input. For example, wrist-wearable device 1302 can detect the hand gesture associated with initiating the messaging application and cause HIPD 1306 to run the messaging application and coordinate the presentation of the messaging application.

Further, user 1308 can provide a user input provided at wrist-wearable device 1302, AR glasses 1304, and/or HIPD 1306 to continue and/or complete an operation initiated at another device. For example, after initiating the messaging application via wrist-wearable device 1302 and while AR glasses 1304 present messaging user interface 1316, user 1308 can provide an input at HIPD 1306 to prepare a response (e.g., shown by the swipe gesture performed on HIPD 1306). Gestures performed by user 1308 on HIPD 1306 can be provided and/or displayed on another device. For example, a swipe gestured performed on HIPD 1306 is displayed on a virtual keyboard of messaging user interface 1316 displayed by AR glasses 1304.

In some embodiments, wrist-wearable device 1302, AR glasses 1304, HIPD 1306, and/or any other communicatively coupled device can present one or more notifications to user 1308. The notification can be an indication of a new message, an incoming call, an application update, a status update, etc. User 1308 can select the notification via wrist-wearable device 1302, AR glasses 1304, and/or HIPD 1306 and can cause presentation of an application or operation associated with the notification on at least one device. For example, user 1308 can receive a notification that a message was received at wrist-wearable device 1302, AR glasses 1304, HIPD 1306, and/or any other communicatively coupled device and can then provide a user input at wrist-wearable device 1302, AR glasses 1304, and/or HIPD 1306 to review the notification, and the device detecting the user input can cause an application associated with the notification to be initiated and/or presented at wrist-wearable device 1302, AR glasses 1304, and/or HIPD 1306.

While the above example describes coordinated inputs used to interact with a messaging application, user inputs can be coordinated to interact with any number of applications including, but not limited to, gaming applications, social media applications, camera applications, web-based applications, financial applications, etc. For example, AR glasses 1304 can present to user 1308 game application data, and HIPD 1306 can be used as a controller to provide inputs to the game. Similarly, user 1308 can use wrist-wearable device 1302 to initiate a camera of AR glasses 1304, and user 308 can use wrist-wearable device 1302, AR glasses 1304, and/or HIPD 1306 to manipulate the image capture (e.g., zoom in or out, apply filters, etc.) and capture image data.

Users may interact with the devices disclosed herein in a variety of ways. For example, as shown in FIGS. 14A and 14B, a user 1408 may interact with an AR system 1400 by donning a VR headset 1450 while holding HIPD 1406 and wearing wrist-wearable device 1402. In this example, AR system 1400 may enable a user to interact with a game 1410 by swiping their arm. One or more of VR headset 1450, HIPD 1406, and wrist-wearable device 1402 may detect this gesture and, in response, may display a sword strike in game 1410. Similarly, in FIGS. 15A and 15B, a user 1508 may interact with an AR system 1500 by donning a VR headset 1520 while wearing haptic device 1560 and wrist-wearable device 1530. In this example, AR system 1500 may enable a user to interact with a game 1510 by swiping their arm. One or more of VR headset 1520, haptic device 1560, and wrist-wearable device 1530 may detect this gesture and, in response, may display a spell being cast in game 1410.

Having discussed example AR systems, devices for interacting with such AR systems and other computing systems more generally will now be discussed in greater detail. Some explanations of devices and components that can be included in some or all of the example devices discussed below are explained herein for ease of reference. Certain types of the components described below may be more suitable for a particular set of devices, and less suitable for a different set of devices. But subsequent reference to the components explained here should be considered to be encompassed by the descriptions provided.

In some embodiments discussed below, example devices and systems, including electronic devices and systems, will be addressed. Such example devices and systems are not intended to be limiting, and one of skill in the art will understand that alternative devices and systems to the example devices and systems described herein may be used to perform the operations and construct the systems and devices that are described herein.

An electronic device may be a device that uses electrical energy to perform a specific function. An electronic device can be any physical object that contains electronic components such as transistors, resistors, capacitors, diodes, and integrated circuits. Examples of electronic devices include smartphones, laptops, digital cameras, televisions, gaming consoles, and music players, as well as the example electronic devices discussed herein. As described herein, an intermediary electronic device may be a device that sits between two other electronic devices and/or a subset of components of one or more electronic devices and facilitates communication, data processing, and/or data transfer between the respective electronic devices and/or electronic components.

An integrated circuit may be an electronic device made up of multiple interconnected electronic components such as transistors, resistors, and capacitors. These components may be etched onto a small piece of semiconductor material, such as silicon. Integrated circuits may include analog integrated circuits, digital integrated circuits, mixed signal integrated circuits, and/or any other suitable type or form of integrated circuit. Examples of integrated circuits include application-specific integrated circuits (ASICs), processing units, central processing units (CPUs), co-processors, and accelerators.

Analog integrated circuits, such as sensors, power management circuits, and operational amplifiers, may process continuous signals and perform analog functions such as amplification, active filtering, demodulation, and mixing. Examples of analog integrated circuits include linear integrated circuits and radio frequency circuits.

Digital integrated circuits, which may be referred to as logic integrated circuits, may include microprocessors, microcontrollers, memory chips, interfaces, power management circuits, programmable devices, and/or any other suitable type or form of integrated circuit. In some embodiments, examples of integrated circuits include central processing units (CPUs),

Processing units, such as CPUs, may be electronic components that are responsible for executing instructions and controlling the operation of an electronic device (e.g., a computer). There are various types of processors that may be used interchangeably, or may be specifically required, by embodiments described herein. For example, a processor may be: (i) a general processor designed to perform a wide range of tasks, such as running software applications, managing operating systems, and performing arithmetic and logical operations; (ii) a microcontroller designed for specific tasks such as controlling electronic devices, sensors, and motors; (iii) an accelerator, such as a graphics processing unit (GPU), designed to accelerate the creation and rendering of images, videos, and animations (e.g., virtual-reality animations, such as three-dimensional modeling); (iv) a field-programmable gate array (FPGA) that can be programmed and reconfigured after manufacturing and/or can be customized to perform specific tasks, such as signal processing, cryptography, and machine learning; and/or (v) a digital signal processor (DSP) designed to perform mathematical operations on signals such as audio, video, and radio waves. One or more processors of one or more electronic devices may be used in various embodiments described herein.

Memory generally refers to electronic components in a computer or electronic device that store data and instructions for the processor to access and manipulate. Examples of memory can include: (i) random access memory (RAM) configured to store data and instructions temporarily; (ii) read-only memory (ROM) configured to store data and instructions permanently (e.g., one or more portions of system firmware, and/or boot loaders) and/or semi-permanently; (iii) flash memory, which can be configured to store data in electronic devices (e.g., USB drives, memory cards, and/or solid-state drives (SSDs)); and/or (iv) cache memory configured to temporarily store frequently accessed data and instructions. Memory, as described herein, can store structured data (e.g., SQL databases, MongoDB databases, GraphQL data, JSON data, etc.). Other examples of data stored in memory can include (i) profile data, including user account data, user settings, and/or other user data stored by the user, (ii) sensor data detected and/or otherwise obtained by one or more sensors, (iii) media content data including stored image data, audio data, documents, and the like, (iv) application data, which can include data collected and/or otherwise obtained and stored during use of an application, and/or any other types of data described herein.

Controllers may be electronic components that manage and coordinate the operation of other components within an electronic device (e.g., controlling inputs, processing data, and/or generating outputs). Examples of controllers can include: (i) microcontrollers, including small, low-power controllers that are commonly used in embedded systems and Internet of Things (IoT) devices; (ii) programmable logic controllers (PLCs) that may be configured to be used in industrial automation systems to control and monitor manufacturing processes; (iii) system-on-a-chip (SoC) controllers that integrate multiple components such as processors, memory, I/O interfaces, and other peripherals into a single chip; and/or (iv) DSPs.

A power system of an electronic device may be configured to convert incoming electrical power into a form that can be used to operate the device. A power system can include various components, such as (i) a power source, which can be an alternating current (AC) adapter or a direct current (DC) adapter power supply, (ii) a charger input, which can be configured to use a wired and/or wireless connection (which may be part of a peripheral interface, such as a USB, micro-USB interface, near-field magnetic coupling, magnetic inductive and magnetic resonance charging, and/or radio frequency (RF) charging), (iii) a power-management integrated circuit, configured to distribute power to various components of the device and to ensure that the device operates within safe limits (e.g., regulating voltage, controlling current flow, and/or managing heat dissipation), and/or (iv) a battery configured to store power to provide usable power to components of one or more electronic devices.

Peripheral interfaces may be electronic components (e.g., of electronic devices) that allow electronic devices to communicate with other devices or peripherals and can provide the ability to input and output data and signals. Examples of peripheral interfaces can include (i) universal serial bus (USB) and/or micro-USB interfaces configured for connecting devices to an electronic device, (ii) Bluetooth interfaces configured to allow devices to communicate with each other, including Bluetooth low energy (BLE), (iii) near field communication (NFC) interfaces configured to be short-range wireless interfaces for operations such as access control, (iv) POGO pins, which may be small, spring-loaded pins configured to provide a charging interface, (v) wireless charging interfaces, (vi) GPS interfaces, (vii) Wi-Fi interfaces for providing a connection between a device and a wireless network, and/or (viii) sensor interfaces.

Sensors may be electronic components (e.g., in and/or otherwise in electronic communication with electronic devices, such as wearable devices) configured to detect physical and environmental changes and generate electrical signals. Examples of sensors can include (i) imaging sensors for collecting imaging data (e.g., including one or more cameras disposed on a respective electronic device), (ii) biopotential-signal sensors, (iii) inertial measurement units (e.g., IMUs) for detecting, for example, angular rate, force, magnetic field, and/or changes in acceleration, (iv) heart rate sensors for measuring a user's heart rate, (v) SpO2 sensors for measuring blood oxygen saturation and/or other biometric data of a user, (vi) capacitive sensors for detecting changes in potential at a portion of a user's body (e.g., a sensor-skin interface), and/or (vii) light sensors (e.g., time-of-flight sensors, infrared light sensors, visible light sensors, etc.).

Biopotential-signal-sensing components may be devices used to measure electrical activity within the body (e.g., biopotential-signal sensors). Some types of biopotential-signal sensors include (i) electroencephalography (EEG) sensors configured to measure electrical activity in the brain to diagnose neurological disorders, (ii) electrocardiogramar EKG) sensors configured to measure electrical activity of the heart to diagnose heart problems, (iii) electromyography (EMG) sensors configured to measure the electrical activity of muscles and to diagnose neuromuscular disorders, and (iv) electrooculography (EOG) sensors configure to measure the electrical activity of eye muscles to detect eye movement and diagnose eye disorders.

An application stored in memory of an electronic device (e.g., software) may include instructions stored in the memory. Examples of such applications include (i) games, (ii) word processors, (iii) messaging applications, (iv) media-streaming applications, (v) financial applications, (vi) calendars. (vii) clocks, and (viii) communication interface modules for enabling wired and/or wireless connections between different respective electronic devices (e.g., IEEE 1802.15.4, Wi-Fi, ZigBee, 6LoWPAN, Thread, Z-Wave, Bluetooth Smart, ISA100.11a, WirelessHART, or MiWi), custom or standard wired protocols (e.g., Ethernet or HomePlug), and/or any other suitable communication protocols).

A communication interface may be a mechanism that enables different systems or devices to exchange information and data with each other, including hardware, software, or a combination of both hardware and software. For example, a communication interface can refer to a physical connector and/or port on a device that enables communication with other devices (e.g., USB, Ethernet, HDMI, Bluetooth). In some embodiments, a communication interface can refer to a software layer that enables different software programs to communicate with each other (e.g., application programming interfaces (APIs), protocols like HTTP and TCP/IP, etc.).

A graphics module may be a component or software module that is designed to handle graphical operations and/or processes and can include a hardware module and/or a software module.

Non-transitory computer-readable storage media may be physical devices or storage media that can be used to store electronic data in a non-transitory form (e.g., such that the data is stored permanently until it is intentionally deleted or modified).

FIGS. 16 and 17 illustrate an example wrist-wearable device 1600 and an example computer system 1700, in accordance with some embodiments. Wrist-wearable device 1600 is an instance of wearable device 1202 described in FIG. 12 herein, such that the wearable device 1202 should be understood to have the features of the wrist-wearable device 1600 and vice versa. FIG. 17 illustrates components of the wrist-wearable device 1600, which can be used individually or in combination, including combinations that include other electronic devices and/or electronic components.

FIG. 16 shows a wearable band 1610 and a watch body 1620 (or capsule) being coupled, as discussed below, to form wrist-wearable device 1600. Wrist-wearable device 1600 can perform various functions and/or operations associated with navigating through user interfaces and selectively opening applications as well as the functions and/or operations described above with reference to FIGS. 12-15B.

As will be described in more detail below, operations executed by wrist-wearable device 1600 can include (i) presenting content to a user (e.g., displaying visual content via a display 1605), (ii) detecting (e.g., sensing) user input (e.g., sensing a touch on peripheral button 1623 and/or at a touch screen of the display 1605, a hand gesture detected by sensors (e.g., biopotential sensors)), (iii) sensing biometric data (e.g., neuromuscular signals, heart rate, temperature, sleep, etc.) via one or more sensors 1613, messaging (e.g., text, speech, video, etc.); image capture via one or more imaging devices or cameras 1625, wireless communications (e.g., cellular, near field, Wi-Fi, personal area network, etc.), location determination, financial transactions, providing haptic feedback, providing alarms, providing notifications, providing biometric authentication, providing health monitoring, providing sleep monitoring, etc.

The above-example functions can be executed independently in watch body 1620, independently in wearable band 1610, and/or via an electronic communication between watch body 1620 and wearable band 1610. In some embodiments, functions can be executed on wrist-wearable device 1600 while an AR environment is being presented (e.g., via one of AR systems 1200 to 1500). The wearable devices described herein can also be used with other types of AR environments.

Wearable band 1610 can be configured to be worn by a user such that an inner surface of a wearable structure 1611 of wearable band 1610 is in contact with the user's skin. In this example, when worn by a user, sensors 1613 may contact the user's skin. In some examples, one or more of sensors 1613 can sense biometric data such as a user's heart rate, a saturated oxygen level, temperature, sweat level, neuromuscular signals, or a combination thereof. One or more of sensors 1613 can also sense data about a user's environment including a user's motion, altitude, location, orientation, gait, acceleration, position, or a combination thereof. In some embodiment, one or more of sensors 1613 can be configured to track a position and/or motion of wearable band 1610. One or more of sensors 1613 can include any of the sensors defined above and/or discussed below with respect to FIG. 16.

One or more of sensors 1613 can be distributed on an inside and/or an outside surface of wearable band 1610. In some embodiments, one or more of sensors 1613 are uniformly spaced along wearable band 1610. Alternatively, in some embodiments, one or more of sensors 1613 are positioned at distinct points along wearable band 1610. As shown in FIG. 16, one or more of sensors 1613 can be the same or distinct. For example, in some embodiments, one or more of sensors 1613 can be shaped as a pill (e.g., sensor 1613a), an oval, a circle a square, an oblong (e.g., sensor 1613c) and/or any other shape that maintains contact with the user's skin (e.g., such that neuromuscular signal and/or other biometric data can be accurately measured at the user's skin). In some embodiments, one or more sensors of 1613 are aligned to form pairs of sensors (e.g., for sensing neuromuscular signals based on differential sensing within each respective sensor). For example, sensor 1613b may be aligned with an adjacent sensor to form sensor pair 1614a and sensor 1613d may be aligned with an adjacent sensor to form sensor pair 1614b. In some embodiments, wearable band 1610 does not have a sensor pair. Alternatively, in some embodiments, wearable band 1610 has a predetermined number of sensor pairs (one pair of sensors, three pairs of sensors, four pairs of sensors, six pairs of sensors, sixteen pairs of sensors, etc.).

Wearable band 1610 can include any suitable number of sensors 1613. In some embodiments, the number and arrangement of sensors 1613 depends on the particular application for which wearable band 1610 is used. For instance, wearable band 1610 can be configured as an armband, wristband, or chest-band that include a plurality of sensors 1613 with different number of sensors 1613, a variety of types of individual sensors with the plurality of sensors 1613, and different arrangements for each use case, such as medical use cases as compared to gaming or general day-to-day use cases.

In accordance with some embodiments, wearable band 1610 further includes an electrical ground electrode and a shielding electrode. The electrical ground and shielding electrodes, like the sensors 1613, can be distributed on the inside surface of the wearable band 1610 such that they contact a portion of the user's skin. For example, the electrical ground and shielding electrodes can be at an inside surface of a coupling mechanism 1616 or an inside surface of a wearable structure 1611. The electrical ground and shielding electrodes can be formed and/or use the same components as sensors 1613. In some embodiments, wearable band 1610 includes more than one electrical ground electrode and more than one shielding electrode.

Sensors 1613 can be formed as part of wearable structure 1611 of wearable band 1610. In some embodiments, sensors 1613 are flush or substantially flush with wearable structure 1611 such that they do not extend beyond the surface of wearable structure 1611. While flush with wearable structure 1611, sensors 1613 are still configured to contact the user's skin (e.g., via a skin-contacting surface). Alternatively, in some embodiments, sensors 1613 extend beyond wearable structure 1611 a predetermined distance (e.g., 0.1-2 mm) to make contact and depress into the user's skin. In some embodiment, sensors 1613 are coupled to an actuator (not shown) configured to adjust an extension height (e.g., a distance from the surface of wearable structure 1611) of sensors 1613 such that sensors 1613 make contact and depress into the user's skin. In some embodiments, the actuators adjust the extension height between 0.01 mm-1.2 mm. This may allow a the user to customize the positioning of sensors 1613 to improve the overall comfort of the wearable band 1610 when worn while still allowing sensors 1613 to contact the user's skin. In some embodiments, sensors 1613 are indistinguishable from wearable structure 1611 when worn by the user.

Wearable structure 1611 can be formed of an elastic material, elastomers, etc., configured to be stretched and fitted to be worn by the user. In some embodiments, wearable structure 1611 is a textile or woven fabric. As described above, sensors 1613 can be formed as part of a wearable structure 1611. For example, sensors 1613 can be molded into the wearable structure 1611, be integrated into a woven fabric (e.g., sensors 1613 can be sewn into the fabric and mimic the pliability of fabric and can and/or be constructed from a series woven strands of fabric).

Wearable structure 1611 can include flexible electronic connectors that interconnect sensors 1613, the electronic circuitry, and/or other electronic components (described below in reference to FIG. 17) that are enclosed in wearable band 1610. In some embodiments, the flexible electronic connectors are configured to interconnect sensors 1613, the electronic circuitry, and/or other electronic components of wearable band 1610 with respective sensors and/or other electronic components of another electronic device (e.g., watch body 1620). The flexible electronic connectors are configured to move with wearable structure 1611 such that the user adjustment to wearable structure 1611 (e.g., resizing, pulling, folding, etc.) does not stress or strain the electrical coupling of components of wearable band 1610.

As described above, wearable band 1610 is configured to be worn by a user. In particular, wearable band 1610 can be shaped or otherwise manipulated to be worn by a user. For example, wearable band 1610 can be shaped to have a substantially circular shape such that it can be configured to be worn on the user's lower arm or wrist. Alternatively, wearable band 1610 can be shaped to be worn on another body part of the user, such as the user's upper arm (e.g., around a bicep), forearm, chest, legs, etc. Wearable band 1610 can include a retaining mechanism 1612 (e.g., a buckle, a hook and loop fastener, etc.) for securing wearable band 1610 to the user's wrist or other body part. While wearable band 1610 is worn by the user, sensors 1613 sense data (referred to as sensor data) from the user's skin. In some examples, sensors 1613 of wearable band 1610 obtain (e.g., sense and record) neuromuscular signals.

The sensed data (e.g., sensed neuromuscular signals) can be used to detect and/or determine the user's intention to perform certain motor actions. In some examples, sensors 1613 may sense and record neuromuscular signals from the user as the user performs muscular activations (e.g., movements, gestures, etc.). The detected and/or determined motor actions (e.g., phalange (or digit) movements, wrist movements, hand movements, and/or other muscle intentions) can be used to determine control commands or control information (instructions to perform certain commands after the data is sensed) for causing a computing device to perform one or more input commands. For example, the sensed neuromuscular signals can be used to control certain user interfaces displayed on display 1605 of wrist-wearable device 1600 and/or can be transmitted to a device responsible for rendering an artificial-reality environment (e.g., a head-mounted display) to perform an action in an associated artificial-reality environment, such as to control the motion of a virtual device displayed to the user. The muscular activations performed by the user can include static gestures, such as placing the user's hand palm down on a table, dynamic gestures, such as grasping a physical or virtual object, and covert gestures that are imperceptible to another person, such as slightly tensing a joint by co-contracting opposing muscles or using sub-muscular activations. The muscular activations performed by the user can include symbolic gestures (e.g., gestures mapped to other gestures, interactions, or commands, for example, based on a gesture vocabulary that specifies the mapping of gestures to commands).

The sensor data sensed by sensors 1613 can be used to provide a user with an enhanced interaction with a physical object (e.g., devices communicatively coupled with wearable band 1610) and/or a virtual object in an artificial-reality application generated by an artificial-reality system (e.g., user interface objects presented on the display 1605, or another computing device (e.g., a smartphone)).

In some embodiments, wearable band 1610 includes one or more haptic devices 1746 (e.g., a vibratory haptic actuator) that are configured to provide haptic feedback (e.g., a cutaneous and/or kinesthetic sensation, etc.) to the user's skin. Sensors 1613 and/or haptic devices 1746 (shown in FIG. 17) can be configured to operate in conjunction with multiple applications including, without limitation, health monitoring, social media, games, and artificial reality (e.g., the applications associated with artificial reality).

Wearable band 1610 can also include coupling mechanism 1616 for detachably coupling a capsule (e.g., a computing unit) or watch body 1620 (via a coupling surface of the watch body 1620) to wearable band 1610. For example, a cradle or a shape of coupling mechanism 1616 can correspond to shape of watch body 1620 of wrist-wearable device 1600. In particular, coupling mechanism 1616 can be configured to receive a coupling surface proximate to the bottom side of watch body 1620 (e.g., a side opposite to a front side of watch body 1620 where display 1605 is located), such that a user can push watch body 1620 downward into coupling mechanism 1616 to attach watch body 1620 to coupling mechanism 1616. In some embodiments, coupling mechanism 1616 can be configured to receive a top side of the watch body 1620 (e.g., a side proximate to the front side of watch body 1620 where display 1605 is located) that is pushed upward into the cradle, as opposed to being pushed downward into coupling mechanism 1616. In some embodiments, coupling mechanism 1616 is an integrated component of wearable band 1610 such that wearable band 1610 and coupling mechanism 1616 are a single unitary structure. In some embodiments, coupling mechanism 1616 is a type of frame or shell that allows watch body 1620 coupling surface to be retained within or on wearable band 1610 coupling mechanism 1616 (e.g., a cradle, a tracker band, a support base, a clasp, etc.).

Coupling mechanism 1616 can allow for watch body 1620 to be detachably coupled to the wearable band 1610 through a friction fit, magnetic coupling, a rotation-based connector, a shear-pin coupler, a retention spring, one or more magnets, a clip, a pin shaft, a hook and loop fastener, or a combination thereof. A user can perform any type of motion to couple the watch body 1620 to wearable band 1610 and to decouple the watch body 1620 from the wearable band 1610. For example, a user can twist, slide, turn, push, pull, or rotate watch body 1620 relative to wearable band 1610, or a combination thereof, to attach watch body 1620 to wearable band 1610 and to detach watch body 1620 from wearable band 1610. Alternatively, as discussed below, in some embodiments, the watch body 1620 can be decoupled from the wearable band 1610 by actuation of a release mechanism 1629.

Wearable band 1610 can be coupled with watch body 1620 to increase the functionality of wearable band 1610 (e.g., converting wearable band 1610 into wrist-wearable device 1600, adding an additional computing unit and/or battery to increase computational resources and/or a battery life of wearable band 1610, adding additional sensors to improve sensed data, etc.). As described above, wearable band 1610 and coupling mechanism 1616 are configured to operate independently (e.g., execute functions independently) from watch body 1620. For example, coupling mechanism 1616 can include one or more sensors 1613 that contact a user's skin when wearable band 1610 is worn by the user, with or without watch body 1620 and can provide sensor data for determining control commands.

A user can detach watch body 1620 from wearable band 1610 to reduce the encumbrance of wrist-wearable device 1600 to the user. For embodiments in which watch body 1620 is removable, watch body 1620 can be referred to as a removable structure, such that in these embodiments wrist-wearable device 1600 includes a wearable portion (e.g., wearable band 1610) and a removable structure (e.g., watch body 1620).

Turning to watch body 1620, in some examples watch body 1620 can have a substantially rectangular or circular shape. Watch body 1620 is configured to be worn by the user on their wrist or on another body part. More specifically, watch body 1620 is sized to be easily carried by the user, attached on a portion of the user's clothing, and/or coupled to wearable band 1610 (forming the wrist-wearable device 1600). As described above, watch body 1620 can have a shape corresponding to coupling mechanism 1616 of wearable band 1610. In some embodiments, watch body 1620 includes a single release mechanism 1629 or multiple release mechanisms (e.g., two release mechanisms 1629 positioned on opposing sides of watch body 1620, such as spring-loaded buttons) for decoupling watch body 1620 from wearable band 1610. Release mechanism 1629 can include, without limitation, a button, a knob, a plunger, a handle, a lever, a fastener, a clasp, a dial, a latch, or a combination thereof.

A user can actuate release mechanism 1629 by pushing, turning, lifting, depressing, shifting, or performing other actions on release mechanism 1629. Actuation of release mechanism 1629 can release (e.g., decouple) watch body 1620 from coupling mechanism 1616 of wearable band 1610, allowing the user to use watch body 1620 independently from wearable band 1610 and vice versa. For example, decoupling watch body 1620 from wearable band 1610 can allow a user to capture images using rear-facing camera 1625b. Although release mechanism 1629 is shown positioned at a corner of watch body 1620, release mechanism 1629 can be positioned anywhere on watch body 1620 that is convenient for the user to actuate. In addition, in some embodiments, wearable band 1610 can also include a respective release mechanism for decoupling watch body 1620 from coupling mechanism 1616. In some embodiments, release mechanism 1629 is optional and watch body 1620 can be decoupled from coupling mechanism 1616 as described above (e.g., via twisting, rotating, etc.).

Watch body 1620 can include one or more peripheral buttons 1623 and 1627 for performing various operations at watch body 1620. For example, peripheral buttons 1623 and 1627 can be used to turn on or wake (e.g., transition from a sleep state to an active state) display 1605, unlock watch body 1620, increase or decrease a volume, increase or decrease a brightness, interact with one or more applications, interact with one or more user interfaces, etc. Additionally or alternatively, in some embodiments, display 1605 operates as a touch screen and allows the user to provide one or more inputs for interacting with watch body 1620.

In some embodiments, watch body 1620 includes one or more sensors 1621. Sensors 1621 of watch body 1620 can be the same or distinct from sensors 1613 of wearable band 1610. Sensors 1621 of watch body 1620 can be distributed on an inside and/or an outside surface of watch body 1620. In some embodiments, sensors 1621 are configured to contact a user's skin when watch body 1620 is worn by the user. For example, sensors 1621 can be placed on the bottom side of watch body 1620 and coupling mechanism 1616 can be a cradle with an opening that allows the bottom side of watch body 1620 to directly contact the user's skin. Alternatively, in some embodiments, watch body 1620 does not include sensors that are configured to contact the user's skin (e.g., including sensors internal and/or external to the watch body 1620 that are configured to sense data of watch body 1620 and the surrounding environment). In some embodiments, sensors 1621 are configured to track a position and/or motion of watch body 1620.

Watch body 1620 and wearable band 1610 can share data using a wired communication method (e.g., a Universal Asynchronous Receiver/Transmitter (UART), a USB transceiver, etc.) and/or a wireless communication method (e.g., near field communication, Bluetooth, etc.). For example, watch body 1620 and wearable band 1610 can share data sensed by sensors 1613 and 1621, as well as application and device specific information (e.g., active and/or available applications, output devices (e.g., displays, speakers, etc.), input devices (e.g., touch screens, microphones, imaging sensors, etc.).

In some embodiments, watch body 1620 can include, without limitation, a front-facing camera 1625a and/or a rear-facing camera 1625b, sensors 1621 (e.g., a biometric sensor, an IMU, a heart rate sensor, a saturated oxygen sensor, a neuromuscular signal sensor, an altimeter sensor, a temperature sensor, a bioimpedance sensor, a pedometer sensor, an optical sensor (e.g., imaging sensor 1763), a touch sensor, a sweat sensor, etc.). In some embodiments, watch body 1620 can include one or more haptic devices 1776 (e.g., a vibratory haptic actuator) that is configured to provide haptic feedback (e.g., a cutaneous and/or kinesthetic sensation, etc.) to the user. Sensors 1721 and/or haptic device 1776 can also be configured to operate in conjunction with multiple applications including, without limitation, health monitoring applications, social media applications, game applications, and artificial reality applications (e.g., the applications associated with artificial reality).

As described above, watch body 1620 and wearable band 1610, when coupled, can form wrist-wearable device 1600. When coupled, watch body 1620 and wearable band 1610 may operate as a single device to execute functions (operations, detections, communications, etc.) described herein. In some embodiments, each device may be provided with particular instructions for performing the one or more operations of wrist-wearable device 1600. For example, in accordance with a determination that watch body 1620 does not include neuromuscular signal sensors, wearable band 1610 can include alternative instructions for performing associated instructions (e.g., providing sensed neuromuscular signal data to watch body 1620 via a different electronic device). Operations of wrist-wearable device 1600 can be performed by watch body 1620 alone or in conjunction with wearable band 1610 (e.g., via respective processors and/or hardware components) and vice versa. In some embodiments, operations of wrist-wearable device 1600, watch body 1620, and/or wearable band 1610 can be performed in conjunction with one or more processors and/or hardware components.

As described below with reference to the block diagram of FIG. 17, wearable band 1610 and/or watch body 1620 can each include independent resources required to independently execute functions. For example, wearable band 1610 and/or watch body 1620 can each include a power source (e.g., a battery), a memory, data storage, a processor (e.g., a central processing unit (CPU)), communications, a light source, and/or input/output devices.

FIG. 17 shows block diagrams of a computing system 1730 corresponding to wearable band 1610 and a computing system 1760 corresponding to watch body 1620 according to some embodiments. Computing system 1700 of wrist-wearable device 1600 may include a combination of components of wearable band computing system 1730 and watch body computing system 1760, in accordance with some embodiments.

Watch body 1620 and/or wearable band 1610 can include one or more components shown in watch body computing system 1760. In some embodiments, a single integrated circuit may include all or a substantial portion of the components of watch body computing system 1760 included in a single integrated circuit. Alternatively, in some embodiments, components of the watch body computing system 1760 may be included in a plurality of integrated circuits that are communicatively coupled. In some embodiments, watch body computing system 1760 may be configured to couple (e.g., via a wired or wireless connection) with wearable band computing system 1730, which may allow the computing systems to share components, distribute tasks, and/or perform other operations described herein (individually or as a single device).

Watch body computing system 1760 can include one or more processors 1779, a controller 1777, a peripherals interface 1761, a power system 1795, and memory (e.g., a memory 1780).

Power system 1795 can include a charger input 1796, a power-management integrated circuit (PMIC) 1797, and a battery 1798. In some embodiments, a watch body 1620 and a wearable band 1610 can have respective batteries (e.g., battery 1798 and 1759) and can share power with each other. Watch body 1620 and wearable band 1610 can receive a charge using a variety of techniques. In some embodiments, watch body 1620 and wearable band 1610 can use a wired charging assembly (e.g., power cords) to receive the charge. Alternatively, or in addition, watch body 1620 and/or wearable band 1610 can be configured for wireless charging. For example, a portable charging device can be designed to mate with a portion of watch body 1620 and/or wearable band 1610 and wirelessly deliver usable power to battery 1798 of watch body 1620 and/or battery 1759 of wearable band 1610. Watch body 1620 and wearable band 1610 can have independent power systems (e.g., power system 1795 and 1756, respectively) to enable each to operate independently. Watch body 1620 and wearable band 1610 can also share power (e.g., one can charge the other) via respective PMICs (e.g., PMICs 1797 and 1758) and charger inputs (e.g., 1757 and 1796) that can share power over power and ground conductors and/or over wireless charging antennas.

In some embodiments, peripherals interface 1761 can include one or more sensors 1721. Sensors 1721 can include one or more coupling sensors 1762 for detecting when watch body 1620 is coupled with another electronic device (e.g., a wearable band 1610). Sensors 1721 can include one or more imaging sensors 1763 (e.g., one or more of cameras 1725, and/or separate imaging sensors 1763 (e.g., thermal-imaging sensors)). In some embodiments, sensors 1721 can include one or more SpO2 sensors 1764. In some embodiments, sensors 1721 can include one or more biopotential-signal sensors (e.g., EMG sensors 1765, which may be disposed on an interior, user-facing portion of watch body 1620 and/or wearable band 1610). In some embodiments, sensors 1721 may include one or more capacitive sensors 1766. In some embodiments, sensors 1721 may include one or more heart rate sensors 1767. In some embodiments, sensors 1721 may include one or more IMU sensors 1768. In some embodiments, one or more IMU sensors 1768 can be configured to detect movement of a user's hand or other location where watch body 1620 is placed or held.

In some embodiments, one or more of sensors 1721 may provide an example human-machine interface. For example, a set of neuromuscular sensors, such as EMG sensors 1765, may be arranged circumferentially around wearable band 1610 with an interior surface of EMG sensors 1765 being configured to contact a user's skin. Any suitable number of neuromuscular sensors may be used (e.g., between 2 and 20 sensors). The number and arrangement of neuromuscular sensors may depend on the particular application for which the wearable device is used. For example, wearable band 1610 can be used to generate control information for controlling an augmented reality system, a robot, controlling a vehicle, scrolling through text, controlling a virtual avatar, or any other suitable control task.

In some embodiments, neuromuscular sensors may be coupled together using flexible electronics incorporated into the wireless device, and the output of one or more of the sensing components can be optionally processed using hardware signal processing circuitry (e.g., to perform amplification, filtering, and/or rectification). In other embodiments, at least some signal processing of the output of the sensing components can be performed in software such as processors 1779. Thus, signal processing of signals sampled by the sensors can be performed in hardware, software, or by any suitable combination of hardware and software, as aspects of the technology described herein are not limited in this respect.

Neuromuscular signals may be processed in a variety of ways. For example, the output of EMG sensors 1765 may be provided to an analog front end, which may be configured to perform analog processing (e.g., amplification, noise reduction, filtering, etc.) on the recorded signals. The processed analog signals may then be provided to an analog-to-digital converter, which may convert the analog signals to digital signals that can be processed by one or more computer processors. Furthermore, although this example is as discussed in the context of interfaces with EMG sensors, the embodiments described herein can also be implemented in wearable interfaces with other types of sensors including, but not limited to, mechanomyography (MMG) sensors, sonomyography (SMG) sensors, and electrical impedance tomography (EIT) sensors.

In some embodiments, peripherals interface 1761 includes a near-field communication (NFC) component 1769, a global-position system (GPS) component 1770, a long-term evolution (LTE) component 1771, and/or a Wi-Fi and/or Bluetooth communication component 1772. In some embodiments, peripherals interface 1761 includes one or more buttons 1773 (e.g., peripheral buttons 1623 and 1627 in FIG. 16), which, when selected by a user, cause operation to be performed at watch body 1620. In some embodiments, the peripherals interface 1761 includes one or more indicators, such as a light emitting diode (LED), to provide a user with visual indicators (e.g., message received, low battery, active microphone and/or camera, etc.).

Watch body 1620 can include at least one display 1605 for displaying visual representations of information or data to a user, including user-interface elements and/or three-dimensional virtual objects. The display can also include a touch screen for inputting user inputs, such as touch gestures, swipe gestures, and the like. Watch body 1620 can include at least one speaker 1774 and at least one microphone 1775 for providing audio signals to the user and receiving audio input from the user. The user can provide user inputs through microphone 1775 and can also receive audio output from speaker 1774 as part of a haptic event provided by haptic controller 1778. Watch body 1620 can include at least one camera 1725, including a front camera 1725a and a rear camera 1725b. Cameras 1725 can include ultra-wide-angle cameras, wide angle cameras, fish-eye cameras, spherical cameras, telephoto cameras, depth-sensing cameras, or other types of cameras.

Watch body computing system 1760 can include one or more haptic controllers 1778 and associated componentry (e.g., haptic devices 1776) for providing haptic events at watch body 1620 (e.g., a vibrating sensation or audio output in response to an event at the watch body 1620). Haptic controllers 1778 can communicate with one or more haptic devices 1776, such as electroacoustic devices, including a speaker of the one or more speakers 1774 and/or other audio components and/or electromechanical devices that convert energy into linear motion such as a motor, solenoid, electroactive polymer, piezoelectric actuator, electrostatic actuator, or other tactile output generating components (e.g., a component that converts electrical signals into tactile outputs on the device). Haptic controller 1778 can provide haptic events to that are capable of being sensed by a user of watch body 1620. In some embodiments, one or more haptic controllers 1778 can receive input signals from an application of applications 1782.

In some embodiments, wearable band computing system 1730 and/or watch body computing system 1760 can include memory 1780, which can be controlled by one or more memory controllers of controllers 1777. In some embodiments, software components stored in memory 1780 include one or more applications 1782 configured to perform operations at the watch body 1620. In some embodiments, one or more applications 1782 may include games, word processors, messaging applications, calling applications, web browsers, social media applications, media streaming applications, financial applications, calendars, clocks, etc. In some embodiments, software components stored in memory 1780 include one or more communication interface modules 1783 as defined above. In some embodiments, software components stored in memory 1780 include one or more graphics modules 1784 for rendering, encoding, and/or decoding audio and/or visual data and one or more data management modules 1785 for collecting, organizing, and/or providing access to data 1787 stored in memory 1780. In some embodiments, one or more of applications 1782 and/or one or more modules can work in conjunction with one another to perform various tasks at the watch body 1620.

In some embodiments, software components stored in memory 1780 can include one or more operating systems 1781 (e.g., a Linux-based operating system, an Android operating system, etc.). Memory 1780 can also include data 1787. Data 1787 can include profile data 1788A, sensor data 1789A, media content data 1790, and application data 1791.

It should be appreciated that watch body computing system 1760 is an example of a computing system within watch body 1620, and that watch body 1620 can have more or fewer components than shown in watch body computing system 1760, can combine two or more components, and/or can have a different configuration and/or arrangement of the components. The various components shown in watch body computing system 1760 are implemented in hardware, software, firmware, or a combination thereof, including one or more signal processing and/or application-specific integrated circuits.

Turning to the wearable band computing system 1730, one or more components that can be included in wearable band 1610 are shown. Wearable band computing system 1730 can include more or fewer components than shown in watch body computing system 1760, can combine two or more components, and/or can have a different configuration and/or arrangement of some or all of the components. In some embodiments, all, or a substantial portion of the components of wearable band computing system 1730 are included in a single integrated circuit. Alternatively, in some embodiments, components of wearable band computing system 1730 are included in a plurality of integrated circuits that are communicatively coupled. As described above, in some embodiments, wearable band computing system 1730 is configured to couple (e.g., via a wired or wireless connection) with watch body computing system 1760, which allows the computing systems to share components, distribute tasks, and/or perform other operations described herein (individually or as a single device).

Wearable band computing system 1730, similar to watch body computing system 1760, can include one or more processors 1749, one or more controllers 1747 (including one or more haptics controllers 1748), a peripherals interface 1731 that can includes one or more sensors 1713 and other peripheral devices, a power source (e.g., a power system 1756), and memory (e.g., a memory 1750) that includes an operating system (e.g., an operating system 1751), data (e.g., data 1754 including profile data 1788B, sensor data 1789B, etc.), and one or more modules (e.g., a communications interface module 1752, a data management module 1753, etc.).

One or more of sensors 1713 can be analogous to sensors 1721 of watch body computing system 1760. For example, sensors 1713 can include one or more coupling sensors 1732, one or more SpO2 sensors 1734, one or more EMG sensors 1735, one or more capacitive sensors 1736, one or more heart rate sensors 1737, and one or more IMU sensors 1738.

Peripherals interface 1731 can also include other components analogous to those included in peripherals interface 1761 of watch body computing system 1760, including an NFC component 1739, a GPS component 1740, an LTE component 1741, a Wi-Fi and/or Bluetooth communication component 1742, and/or one or more haptic devices 1746 as described above in reference to peripherals interface 1761. In some embodiments, peripherals interface 1731 includes one or more buttons 1743, a display 1733, a speaker 1744, a microphone 1745, and a camera 1755. In some embodiments, peripherals interface 1731 includes one or more indicators, such as an LED.

It should be appreciated that wearable band computing system 1730 is an example of a computing system within wearable band 1610, and that wearable band 1610 can have more or fewer components than shown in wearable band computing system 1730, combine two or more components, and/or have a different configuration and/or arrangement of the components. The various components shown in wearable band computing system 1730 can be implemented in one or more of a combination of hardware, software, or firmware, including one or more signal processing and/or application-specific integrated circuits.

Wrist-wearable device 1600 with respect to FIG. 16 is an example of wearable band 1610 and watch body 1620 coupled together, so wrist-wearable device 1600 will be understood to include the components shown and described for wearable band computing system 1730 and watch body computing system 1760. In some embodiments, wrist-wearable device 1600 has a split architecture (e.g., a split mechanical architecture, a split electrical architecture, etc.) between watch body 1620 and wearable band 1610. In other words, all of the components shown in wearable band computing system 1730 and watch body computing system 1760 can be housed or otherwise disposed in a combined wrist-wearable device 1600 or within individual components of watch body 1620, wearable band 1610, and/or portions thereof (e.g., a coupling mechanism 1616 of wearable band 1610).

The techniques described above can be used with any device for sensing neuromuscular signals but could also be used with other types of wearable devices for sensing neuromuscular signals (such as body-wearable or head-wearable devices that might have neuromuscular sensors closer to the brain or spinal column).

In some embodiments, wrist-wearable device 1600 can be used in conjunction with a head-wearable device (e.g., AR glasses 1800 and VR system 1910) and/or an HIPD, and wrist-wearable device 1600 can also be configured to be used to allow a user to control any aspect of the artificial reality (e.g., by using EMG-based gestures to control user interface objects in the artificial reality and/or by allowing a user to interact with the touchscreen on the wrist-wearable device to also control aspects of the artificial reality). Having thus described example wrist-wearable devices, attention will now be turned to example head-wearable devices, such AR glasses 1800 and VR headset 1910.

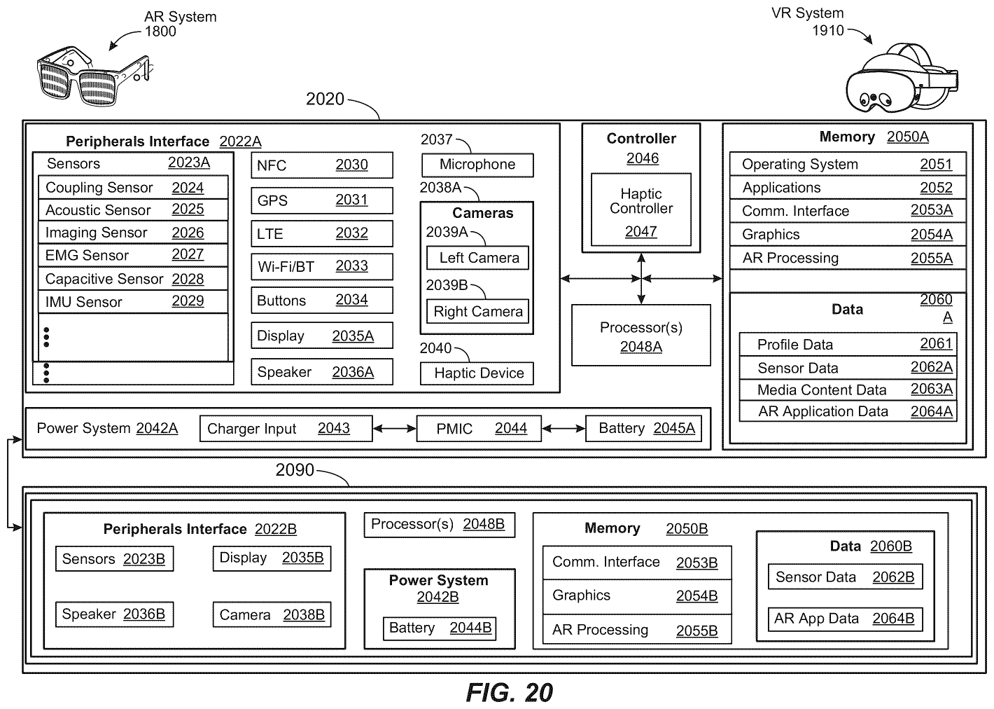

FIGS. 18 to 20 show example artificial-reality systems, which can be used as or in connection with wrist-wearable device 1600. In some embodiments, AR system 1800 includes an eyewear device 1802, as shown in FIG. 18. In some embodiments, VR system 1910 includes a head-mounted display (HMD) 1912, as shown in FIGS. 19A and 19B. In some embodiments, AR system 1800 and VR system 1910 can include one or more analogous components (e.g., components for presenting interactive artificial-reality environments, such as processors, memory, and/or presentation devices, including one or more displays and/or one or more waveguides), some of which are described in more detail with respect to FIG. 20. As described herein, a head-wearable device can include components of eyewear device 1802 and/or head-mounted display 1912. Some embodiments of head-wearable devices do not include any displays, including any of the displays described with respect to AR system 1800 and/or VR system 1910. While the example artificial-reality systems are respectively described herein as AR system 1800 and VR system 1910, either or both of the example AR systems described herein can be configured to present fully-immersive virtual-reality scenes presented in substantially all of a user's field of view or subtler augmented-reality scenes that are presented within a portion, less than all, of the user's field of view.

FIG. 18 show an example visual depiction of AR system 1800, including an eyewear device 1802 (which may also be described herein as augmented-reality glasses, and/or smart glasses). AR system 1800 can include additional electronic components that are not shown in FIG. 18, such as a wearable accessory device and/or an intermediary processing device, in electronic communication or otherwise configured to be used in conjunction with the eyewear device 1802. In some embodiments, the wearable accessory device and/or the intermediary processing device may be configured to couple with eyewear device 1802 via a coupling mechanism in electronic communication with a coupling sensor 2024 (FIG. 20), where coupling sensor 2024 can detect when an electronic device becomes physically or electronically coupled with eyewear device 1802. In some embodiments, eyewear device 1802 can be configured to couple to a housing 2090 (FIG. 20), which may include one or more additional coupling mechanisms configured to couple with additional accessory devices. The components shown in FIG. 18 can be implemented in hardware, software, firmware, or a combination thereof, including one or more signal-processing components and/or application-specific integrated circuits (ASICs).

Eyewear device 1802 includes mechanical glasses components, including a frame 1804 configured to hold one or more lenses (e.g., one or both lenses 1806-1 and 1806-2). One of ordinary skill in the art will appreciate that eyewear device 1802 can include additional mechanical components, such as hinges configured to allow portions of frame 1804 of eyewear device 1802 to be folded and unfolded, a bridge configured to span the gap between lenses 1806-1 and 1806-2 and rest on the user's nose, nose pads configured to rest on the bridge of the nose and provide support for eyewear device 1802, earpieces configured to rest on the user's ears and provide additional support for eyewear device 1802, temple arms configured to extend from the hinges to the earpieces of eyewear device 1802, and the like. One of ordinary skill in the art will further appreciate that some examples of AR system 1800 can include none of the mechanical components described herein. For example, smart contact lenses configured to present artificial reality to users may not include any components of eyewear device 1802.

Eyewear device 1802 includes electronic components, many of which will be described in more detail below with respect to FIG. 10. Some example electronic components are illustrated in FIG. 18, including acoustic sensors 1825-1, 1825-2, 1825-3, 1825-4, 1825-5, and 1825-6, which can be distributed along a substantial portion of the frame 1804 of eyewear device 1802. Eyewear device 1802 also includes a left camera 1839A and a right camera 1839B, which are located on different sides of the frame 1804. Eyewear device 1802 also includes a processor 1848 (or any other suitable type or form of integrated circuit) that is embedded into a portion of the frame 1804.

FIGS. 19A and 19B show a VR system 1910 that includes a head-mounted display (HMD) 1912 (e.g., also referred to herein as an artificial-reality headset, a head-wearable device, a VR headset, etc.), in accordance with some embodiments. As noted, some artificial-reality systems (e.g., AR system 1800) may, instead of blending an artificial reality with actual reality, substantially replace one or more of a user's visual and/or other sensory perceptions of the real world with a virtual experience (e.g., AR systems 1400 and 1500).

HMD 1912 includes a front body 1914 and a frame 1916 (e.g., a strap or band) shaped to fit around a user's head. In some embodiments, front body 1914 and/or frame 1916 include one or more electronic elements for facilitating presentation of and/or interactions with an AR and/or VR system (e.g., displays, IMUs, tracking emitter or detectors). In some embodiments, HMD 1912 includes output audio transducers (e.g., an audio transducer 1918), as shown in FIG. 19B. In some embodiments, one or more components, such as the output audio transducer(s) 1918 and frame 1916, can be configured to attach and detach (e.g., are detachably attachable) to HMD 1912 (e.g., a portion or all of frame 1916, and/or audio transducer 1918), as shown in FIG. 19B. In some embodiments, coupling a detachable component to HMD 1912 causes the detachable component to come into electronic communication with HMD 1912.

FIGS. 19A and 19B also show that VR system 1910 includes one or more cameras, such as left camera 1939A and right camera 1939B, which can be analogous to left and right cameras 1839A and 1839B on frame 1804 of eyewear device 1802. In some embodiments, VR system 1910 includes one or more additional cameras (e.g., cameras 1939C and 1939D), which can be configured to augment image data obtained by left and right cameras 1939A and 1939B by providing more information. For example, camera 1939C can be used to supply color information that is not discerned by cameras 1939A and 1939B. In some embodiments, one or more of cameras 1939A to 1939D can include an optional IR cut filter configured to remove IR light from being received at the respective camera sensors.

FIG. 20 illustrates a computing system 2020 and an optional housing 2090, each of which show components that can be included in AR system 1800 and/or VR system 1910. In some embodiments, more or fewer components can be included in optional housing 2090 depending on practical restraints of the respective AR system being described.

In some embodiments, computing system 2020 can include one or more peripherals interfaces 2022A and/or optional housing 2090 can include one or more peripherals interfaces 2022B. Each of computing system 2020 and optional housing 2090 can also include one or more power systems 2042A and 2042B, one or more controllers 2046 (including one or more haptic controllers 2047), one or more processors 2048A and 2048B (as defined above, including any of the examples provided), and memory 2050A and 2050B, which can all be in electronic communication with each other. For example, the one or more processors 2048A and 2048B can be configured to execute instructions stored in memory 2050A and 2050B, which can cause a controller of one or more of controllers 2046 to cause operations to be performed at one or more peripheral devices connected to peripherals interface 2022A and/or 2022B. In some embodiments, each operation described can be powered by electrical power provided by power system 2042A and/or 2042B.

In some embodiments, peripherals interface 2022A can include one or more devices configured to be part of computing system 2020, some of which have been defined above and/or described with respect to the wrist-wearable devices shown in FIGS. 16 and 17. For example, peripherals interface 2022A can include one or more sensors 2023A. Some example sensors 2023A include one or more coupling sensors 2024, one or more acoustic sensors 2025, one or more imaging sensors 2026, one or more EMG sensors 2027, one or more capacitive sensors 2028, one or more IMU sensors 2029, and/or any other types of sensors explained above or described with respect to any other embodiments discussed herein.

In some embodiments, peripherals interfaces 2022A and 2022B can include one or more additional peripheral devices, including one or more NFC devices 2030, one or more GPS devices 2031, one or more LTE devices 2032, one or more Wi-Fi and/or Bluetooth devices 2033, one or more buttons 2034 (e.g., including buttons that are slidable or otherwise adjustable), one or more displays 2035A and 2035B, one or more speakers 2036A and 2036B, one or more microphones 2037, one or more cameras 2038A and 2038B (e.g., including the left camera 2039A and/or a right camera 2039B), one or more haptic devices 2040, and/or any other types of peripheral devices defined above or described with respect to any other embodiments discussed herein.

AR systems can include a variety of types of visual feedback mechanisms (e.g., presentation devices). For example, display devices in AR system 1800 and/or VR system 1910 can include one or more liquid-crystal displays (LCDs), light emitting diode (LED) displays, organic LED (OLED) displays, and/or any other suitable types of display screens. Artificial-reality systems can include a single display screen (e.g., configured to be seen by both eyes), and/or can provide separate display screens for each eye, which can allow for additional flexibility for varifocal adjustments and/or for correcting a refractive error associated with a user's vision. Some embodiments of AR systems also include optical subsystems having one or more lenses (e.g., conventional concave or convex lenses, Fresnel lenses, or adjustable liquid lenses) through which a user can view a display screen.

For example, respective displays 2035A and 2035B can be coupled to each of the lenses 1806-1 and 1806-2 of AR system 1800. Displays 2035A and 2035B may be coupled to each of lenses 1806-1 and 1806-2, which can act together or independently to present an image or series of images to a user. In some embodiments, AR system 1800 includes a single display 2035A or 2035B (e.g., a near-eye display) or more than two displays 2035A and 2035B. In some embodiments, a first set of one or more displays 2035A and 2035B can be used to present an augmented-reality environment, and a second set of one or more display devices 2035A and 2035B can be used to present a virtual-reality environment. In some embodiments, one or more waveguides are used in conjunction with presenting artificial-reality content to the user of AR system 1800 (e.g., as a means of delivering light from one or more displays 2035A and 2035B to the user's eyes). In some embodiments, one or more waveguides are fully or partially integrated into the eyewear device 1802. Additionally, or alternatively to display screens, some artificial-reality systems include one or more projection systems. For example, display devices in AR system 1800 and/or VR system 1910 can include micro-LED projectors that project light (e.g., using a waveguide) into display devices, such as clear combiner lenses that allow ambient light to pass through. The display devices can refract the projected light toward a user's pupil and can enable a user to simultaneously view both artificial-reality content and the real world. Artificial-reality systems can also be configured with any other suitable type or form of image projection system. In some embodiments, one or more waveguides are provided additionally or alternatively to the one or more display(s) 2035A and 2035B.

Computing system 2020 and/or optional housing 2090 of AR system 1800 or VR system 1910 can include some or all of the components of a power system 2042A and 2042B. Power systems 2042A and 2042B can include one or more charger inputs 2043, one or more PMICs 2044, and/or one or more batteries 2045A and 2044B.

Memory 2050A and 2050B may include instructions and data, some or all of which may be stored as non-transitory computer-readable storage media within the memories 2050A and 2050B. For example, memory 2050A and 2050B can include one or more operating systems 2051, one or more applications 2052, one or more communication interface applications 2053A and 2053B, one or more graphics applications 2054A and 2054B, one or more AR processing applications 2055A and 2055B, and/or any other types of data defined above or described with respect to any other embodiments discussed herein.

Memory 2050A and 2050B also include data 2060A and 2060B, which can be used in conjunction with one or more of the applications discussed above. Data 2060A and 2060B can include profile data 2061, sensor data 2062A and 2062B, media content data 2063A, AR application data 2064A and 2064B, and/or any other types of data defined above or described with respect to any other embodiments discussed herein.

In some embodiments, controller 2046 of eyewear device 1802 may process information generated by sensors 2023A and/or 2023B on eyewear device 1802 and/or another electronic device within AR system 1800. For example, controller 2046 can process information from acoustic sensors 1825-1 and 1825-2. For each detected sound, controller 2046 can perform a direction of arrival (DOA) estimation to estimate a direction from which the detected sound arrived at eyewear device 1802 of R system 1800. As one or more of acoustic sensors 2025 (e.g., the acoustic sensors 1825-1, 1825-2) detects sounds, controller 2046 can populate an audio data set with the information (e.g., represented in FIG. 10 as sensor data 2062A and 2062B).

In some embodiments, a physical electronic connector can convey information between eyewear device 1802 and another electronic device and/or between one or more processors 1848, 2048A, 2048B of AR system 1800 or VR system 1910 and controller 2046. The information can be in the form of optical data, electrical data, wireless data, or any other transmittable data form. Moving the processing of information generated by eyewear device 1802 to an intermediary processing device can reduce weight and heat in the eyewear device, making it more comfortable and safer for a user. In some embodiments, an optional wearable accessory device (e.g., an electronic neckband) is coupled to eyewear device 1802 via one or more connectors. The connectors can be wired or wireless connectors and can include electrical and/or non-electrical (e.g., structural) components. In some embodiments, eyewear device 1802 and the wearable accessory device can operate independently without any wired or wireless connection between them.

In some situations, pairing external devices, such as an intermediary processing device (e.g., HIPD 1206, 1306, 1406) with eyewear device 1802 (e.g., as part of AR system 1800) enables eyewear device 1802 to achieve a similar form factor of a pair of glasses while still providing sufficient battery and computation power for expanded capabilities. Some, or all, of the battery power, computational resources, and/or additional features of AR system 1800 can be provided by a paired device or shared between a paired device and eyewear device 1802, thus reducing the weight, heat profile, and form factor of eyewear device 1802 overall while allowing eyewear device 1802 to retain its desired functionality. For example, the wearable accessory device can allow components that would otherwise be included on eyewear device 1802 to be included in the wearable accessory device and/or intermediary processing device, thereby shifting a weight load from the user's head and neck to one or more other portions of the user's body. In some embodiments, the intermediary processing device has a larger surface area over which to diffuse and disperse heat to the ambient environment. Thus, the intermediary processing device can allow for greater battery and computation capacity than might otherwise have been possible on eyewear device 1802 standing alone. Because weight carried in the wearable accessory device can be less invasive to a user than weight carried in the eyewear device 1802, a user may tolerate wearing a lighter eyewear device and carrying or wearing the paired device for greater lengths of time than the user would tolerate wearing a heavier eyewear device standing alone, thereby enabling an artificial-reality environment to be incorporated more fully into a user's day-to-day activities.

AR systems can include various types of computer vision components and subsystems. For example, AR system 1800 and/or VR system 1910 can include one or more optical sensors such as two-dimensional (2D) or three-dimensional (3D) cameras, time-of-flight depth sensors, structured light transmitters and detectors, single-beam or sweeping laser rangefinders, 3D LiDAR sensors, and/or any other suitable type or form of optical sensor. An AR system can process data from one or more of these sensors to identify a location of a user and/or aspects of the use's real-world physical surroundings, including the locations of real-world objects within the real-world physical surroundings. In some embodiments, the methods described herein are used to map the real world, to provide a user with context about real-world surroundings, and/or to generate digital twins (e.g., interactable virtual objects), among a variety of other functions. For example, FIGS. 19A and 19B show VR system 1910 having cameras 1939A to 1939D, which can be used to provide depth information for creating a voxel field and a two-dimensional mesh to provide object information to the user to avoid collisions.

In some embodiments, AR system 1800 and/or VR system 1910 can include haptic (tactile) feedback systems, which may be incorporated into headwear, gloves, body suits, handheld controllers, environmental devices (e.g., chairs or floormats), and/or any other type of device or system, such as the wearable devices discussed herein. The haptic feedback systems may provide various types of cutaneous feedback, including vibration, force, traction, shear, texture, and/or temperature. The haptic feedback systems may also provide various types of kinesthetic feedback, such as motion and compliance. The haptic feedback may be implemented using motors, piezoelectric actuators, fluidic systems, and/or a variety of other types of feedback mechanisms. The haptic feedback systems may be implemented independently of other artificial-reality devices, within other artificial-reality devices, and/or in conjunction with other artificial-reality devices.

In some embodiments of an artificial reality system, such as AR system 1800 and/or VR system 1910, ambient light (e.g., a live feed of the surrounding environment that a user would normally see) can be passed through a display element of a respective head-wearable device presenting aspects of the AR system. In some embodiments, ambient light can be passed through a portion less that is less than all of an AR environment presented within a user's field of view (e.g., a portion of the AR environment co-located with a physical object in the user's real-world environment that is within a designated boundary (e.g., a guardian boundary) configured to be used by the user while they are interacting with the AR environment). For example, a visual user interface element (e.g., a notification user interface element) can be presented at the head-wearable device, and an amount of ambient light (e.g., 15-50% of the ambient light) can be passed through the user interface element such that the user can distinguish at least a portion of the physical environment over which the user interface element is being displayed

The foregoing description has been presented for illustration; it is not intended to be exhaustive or to limit the scope of the disclosure to the precise forms disclosed. Persons skilled in the relevant art can appreciate that many modifications and variations are possible considering the above disclosure.

Finally, the language used in the specification has been principally selected for readability and instructional purposes, and it may not have been selected to delineate or circumscribe the patent rights. It is therefore intended that the scope of the patent rights be limited not by this detailed description, but rather by any claims that issue on an application based hereon. Accordingly, the disclosure of the examples is intended to be illustrative, but not limiting, of the scope of the patent rights, which is set forth in the following claims.

What is claimed is:

1. An apparatus comprising:
a housing including an electronics cavity containing at least one microchip and a display cavity containing a display screen;
a heat pipe thermally coupled to the at least one microchip of a head-mounted display system such that the heat pipe is configured to cool the at least one microchip; and
a separator wall separating the electronics cavity from the display cavity, wherein the separator wall is positioned directly between at least a portion of the heat pipe and the display screen, wherein the heat pipe is at least partially within the electronics cavity.

2. The apparatus of claim 1, wherein the at least one microchip comprises a system-on-a-chip.

3. The apparatus of claim 1, wherein the at least one microchip comprises a memory chip.

4. The apparatus of claim 1, wherein the separator wall comprises a thermally insulating material.

5. The apparatus of claim 1, wherein the separator wall comprises an air gap.

6. The apparatus of claim 1, wherein the housing comprises an inlet including an opening to allow outside air to enter the housing via the display cavity.

7. The apparatus of claim 6, wherein the housing further comprises an outlet including another opening to allow internal air to exit the housing via the electronics cavity.

8. An apparatus, comprising:
a housing including an electronics cavity containing electronics and a display cavity containing a display screen;
a heat sink disposed in the electronics cavity and configured to draw heat from the electronics within the electronics cavity; and
a separator wall separating the electronics cavity from the display cavity, wherein the separator wall comprises a dual-wall insulating structure defining an air gap, wherein the dual-wall insulating structure is positioned directly between at least a portion of the heat sink and the display screen.

9. The apparatus of claim 8, wherein the housing comprises a head-mounted display housing.

10. The apparatus of claim 8, wherein the electronics comprises at least one microchip.

11. The apparatus of claim 8, wherein the dual-wall insulating structure of the separator wall comprises a first polymer wall adjacent to the heat sink and a second polymer wall separated from the first polymer wall by the air gap.

12. The apparatus of claim 8, wherein the heat sink comprises at least one of:
a vapor chamber;
a heat pipe; and
an ionic fan.

13. The apparatus of claim 12, further comprising at least one fan, wherein the heat sink further comprises at least one set of heat dissipation fins and the at least one fan directs air across the at least one set of heat dissipation fins.

14. The apparatus of claim 12, wherein the heat pipe exhibits a curved orientation.

15. The apparatus of claim 12, wherein the ionic fan is coupled to the separator wall and extends into the electronics cavity.

16. A head-mounted display system, comprising:
a housing including an electronics cavity containing at least one microchip and a display cavity containing at least one near-eye display screen;
a heat sink within the electronics cavity, the heat sink thermally coupled to the at least one microchip and configured to draw heat from the at least one microchip;
a separator wall positioned between the electronics cavity and the display cavity, wherein the separator wall comprises a first wall adjacent to the heat sink, a second wall adjacent to the at least one near-eye display screen, and an insulating gap between the first wall and the second wall.

17. The head-mounted display system of claim 16, wherein the at least one near-eye display screen comprises a first near-eye display screen positioned to display images to a user's right eye and a second near-eye display screen positioned to display images to a user's left eye.

18. The head-mounted display system of claim 17, wherein the at least one microchip is positioned centrally between the first near-eye display screen and the second near-eye display screen.

19. The head-mounted display system of claim 16, wherein the heat sink comprises an ionic fan.

20. The head-mounted display system of claim 19, wherein the ionic fan is coupled to the separator wall and extends into the electronics cavity.
